(19) United States
(12) Patent Application Publication
(10) Pub. No.: US 2025/0341601 A1
(43) Pub. Date: Nov. 6, 2025

(54) SYSTEMS AND METHODS FOR MAGNETIC RESONANCE IMAGING

(71) Applicant: SHANGHAI UNITED IMAGING HEALTHCARE CO., LTD., Shanghai (CN)

(72) Inventor: Yongquan YE, Houston, TX (US)

(73) Assignee: SHANGHAI UNITED IMAGING HEALTHCARE CO., LTD., Shanghai (CN)

(21) Appl. No.: 19/268,959

(22) Filed: Jul. 14, 2025

Related U.S. Application Data
(63) Continuation-in-part of application No. 18/663,040, filed on May 13, 2024, now Pat. No. 12,360,192.
Application No. 18/663,040 is a continuation of application No. 17/651,416, filed on Feb. 16, 2022, now Pat. No. 11,982,728.

(51) Int. Cl. G01R 33/565; G01R 33/56

(52) U.S. Cl. CPC G01R 33/56536; G01R 33/5602; G01R 33/5608

(57) ABSTRACT

A method for magnetic resonance imaging (MRI) may include obtaining a plurality of first magnetic resonance (MR) data sets related to a region of interest (ROI) of a subject. The plurality of first MR data sets may be collected based on two or more different values of a scan parameter. The method may also include determining a plurality of second MR data sets based on the plurality of first MR data sets. Each of the plurality of second MR data sets may correspond to at least two of the plurality of first MR data sets. The method may also include generate, based on the plurality of second MR data sets, a plurality of T1 weighted images of the ROI each of which corresponds to a target time point.

### CROSS-REFERENCE TO RELATED APPLICATIONS

This application is a continuation-in-part of U.S. application Ser. No. 18/663,040, filed on May 13, 2024, which is a continuation of U.S. application Ser. No. 17/651,416 (now U.S. Pat. No. 11,982,728), filed on Feb. 16, 2022, the contents of which are incorporated herein by reference to their entirety.

### TECHNICAL FIELD

This disclosure generally relates to magnetic resonance imaging (MRI), and more particularly, relates to systems and methods for T1 weighted dynamic imaging.

### BACKGROUND

In T1 weighted dynamic imaging, besides T1 information, acquired magnetic resonance (MR) signals also include non-T1 factors, such as proton density, T2* relaxation effect, and receiving coil sensitivity, etc., which may introduce errors and biases to signal analysis, e.g., image reconstruction, physiological analysis, etc. Therefore, it is desirable to provide systems and methods for T1 weighted dynamic imaging to alleviate or eliminate the effect of non-T1 factors on T1 weighted dynamic imaging.

### SUMMARY

According to an aspect of the present disclosure, a system for magnetic resonance imaging (MRI) may include one or more storage devices and one or more processors configured to communicate with the one or more storage devices. The one or more storage devices may include a set of instructions. When the one or more processors executing the set of instructions, the one or more processors may be directed to perform one or more of the following operations. The one or more processors may obtain a plurality of first magnetic resonance (MR) data sets related to a region of interest (ROI) of a subject. The plurality of first MR data sets may be collected based on two or more different values of a scan parameter. The one or more processors may determine a plurality of second MR data sets based on the plurality of first MR data sets. Each of the plurality of second MR data sets may correspond to at least two of the plurality of first MR data sets. The one or more processors may generate, based on the plurality of second MR data sets, a plurality of T1 weighted images of the ROI each of which corresponds to a target time point.

According to another aspect of the present disclosure, a method for magnetic resonance imaging (MRI) may include one or more of the following operations. One or more processors may obtain a plurality of first magnetic resonance (MR) data sets related to a region of interest (ROI) of a subject. The plurality of first MR data sets may be collected based on two or more different values of a scan parameter. The one or more processors may determine a plurality of second MR data sets based on the plurality of first MR data sets. Each of the plurality of second MR data sets may correspond to at least two of the plurality of first MR data sets. The one or more processors may generate, based on the plurality of second MR data sets, a plurality of T1 weighted images of the ROI each of which corresponds to a target time point.

According to yet another aspect of the present disclosure, a system for magnetic resonance imaging (MRI) may include an acquisition module configured to obtain a plurality of first magnetic resonance (MR) data sets related to a region of interest (ROI) of a subject. The plurality of first MR data sets may be collected based on two or more different values of a scan parameter. The system may also include a determination module configured to determine a plurality of second MR data sets based on the plurality of first MR data sets. Each of the plurality of second MR data sets may correspond to at least two of the plurality of first MR data sets. The system may also include a reconstruction module configured to generate, based on the plurality of second MR data sets, a plurality of T1 weighted images of the ROI each of which corresponds to a target time point.

According to yet another aspect of the present disclosure, a non-transitory computer readable medium may comprise at least one set of instructions. The at least one set of instructions may be executed by one or more processors of a computer server. The one or more processors may obtain a plurality of first magnetic resonance (MR) data sets related to a region of interest (ROI) of a subject. The plurality of first MR data sets may be collected based on two or more different values of a scan parameter. The one or more processors may determine a plurality of second MR data sets based on the plurality of first MR data sets. Each of the plurality of second MR data sets may correspond to at least two of the plurality of first MR data sets. The one or more processors may generate, based on the plurality of second MR data sets, a plurality of T1 weighted images of the ROI each of which corresponds to a target time point.

In some embodiments, the at least two of the plurality of first MR data sets corresponding to the each of the plurality of second MR data sets may correspond to two of the two or more different values of the scan parameter.

In some embodiments, to determine the plurality of second MR data sets based on the plurality of first MR data sets, for one of the plurality of second MR data sets, the one or more processors may obtain at least one first MR data set related to a first value of the scan parameter. The one or more processors may obtain at least one first MR data set related to a second value of the scan parameter. The one or more processors may perform division based on the at least two of the plurality of first MR data sets related to the first value and the second value of the scan parameter.

In some embodiments, each of the plurality of first MR data sets may be collected based on one of the two or more values of the scan parameter.

In some embodiments, the scan parameter may include at least one of a flip angle or a repetition time (TR).

In some embodiments, the plurality of first MR data sets may be collected based on two or more different values of the flip angle and a fixed value of the TR; two or more different values of the TR and a fixed value of the flip angle; or two or more different values of the flip angle and two or more different values of the TR. The plurality of first MR data sets may be collected so that any two adjacent first MR data sets correspond to different values of at least one of the flip angle or the TR.

In some embodiments, to determine the plurality of second MR data sets based on the plurality of first MR data sets, for each of the plurality of second MR data sets, the one or more processors may determine the second MR data set by performing division between two adjacent first MR data sets.

In some embodiments, the target time point of one of the plurality of T1 weighted images corresponding to the second MR data set may be designated as an average time point of a time period in which the two adjacent first MR data sets are acquired.

In some embodiments, the plurality of first MR data sets may be collected based on two or more different values of the flip angle and a fixed value of the TR; or two or more different values of the TR and a fixed value of the flip angle. At least one of the plurality of first MR data sets corresponding to a first value of the two or more values of the flip angle or the TR may be collected before the rest of the plurality of first MR data sets corresponding to the rest of the two or more values of the flip angle or the TR.

In some embodiments, the plurality of first MR data sets may be collected based on two or more different values of the flip angle and two or more different values of the TR. At least one of the plurality of first MR data sets corresponding to a first value of the two or more values of the flip angle and a first value of the two or more values of the TR may be collected before the rest of the plurality of first MR data sets corresponding to the rest of the two or more values of the flip angle and the rest of the two or more values of the TR.

In some embodiments, to determine the plurality of second MR data sets based on the plurality of first MR data sets, the one or more processors may determine an average of the at least one of the plurality of first MR data sets. For each of the plurality of second MR data sets, the one or more processors may determine the second MR data set by performing division between the average and one of the rest of the plurality of first MR data sets.

In some embodiments, the target time point of one of the plurality of T1 weighted images corresponding to the second MR data set is designated as a time point in a time period in which the one of the rest of the plurality of first MR data sets is acquired.

In some embodiments, at least one of the plurality of first MR data sets may be acquired before an injection of a contrast agent into the ROI, and the rest of the plurality of first MR data sets is acquired after the injection of the contrast agent.

In some embodiments, the one or more processors may perform T1 mapping based on the plurality of first MR data sets.

In some embodiments, the one or more processors may estimate a contrast agent concentration corresponding to each target time point based on the plurality of T1 weighted images and the T1 mapping. The one or more processors may perform physiological analysis of the ROI based on the contrast agent concentration corresponding to each target time point.

In some embodiments, the one or more processors may determine a signal intensity corresponding to each target time point based on the plurality of T1 weighted images. The one or more processors may perform physiological analysis of the ROI based on the signal intensity corresponding to each target time point.

Additional features will be set forth in part in the description which follows, and in part will become apparent to those skilled in the art upon examination of the following and the accompanying drawings or may be learned by production or operation of the examples. The features of the present disclosure may be realized and attained by practice or use of various aspects of the methodologies, instrumentalities and combinations set forth in the detailed examples discussed below.

### BRIEF DESCRIPTION OF THE DRAWINGS

The present disclosure is further described in terms of exemplary embodiments. These exemplary embodiments are described in detail with reference to the drawings. The drawings are not to scale. These embodiments are non-limiting exemplary embodiments, in which like reference numerals represent similar structures throughout the several views of the drawings, and wherein:

FIG. 1 is a schematic diagram illustrating an exemplary MRI system according to some embodiments of the present disclosure;

FIG. 2 is a schematic diagram illustrating an exemplary MRI device according to some embodiments of the present disclosure;

FIG. 3 is a schematic diagram illustrating exemplary hardware and/or software components of a computing device according to some embodiments of the present disclosure;

FIG. 4 is a schematic diagram illustrating exemplary hardware and/or software components of a mobile device may be implemented according to some embodiments of the present disclosure;

FIG. 5 is a schematic diagram illustrating an exemplary processing device according to some embodiments of the present disclosure;

FIG. 6 is a flowchart illustrating an exemplary process for generating a plurality of T1 weighted images according to some embodiments of the present disclosure;

FIGS. 7A-7C are schematic diagrams illustrating exemplary acquisition of a plurality of first MR data sets according to some embodiments of the present disclosure;

FIGS. 8A-8C are schematic diagrams illustrating exemplary acquisition of a plurality of first MR data sets according to some embodiments of the present disclosure;

FIG. 9 is a schematic diagram illustrating an exemplary intensity-time curve according to some embodiments of the present disclosure;

FIG. 10A is a schematic diagram illustrating an exemplary T1 weighted image generated based on a second MR data set according to some embodiments of the present disclosure; and

FIG. 10B is a schematic diagram illustrating an exemplary T1 weighted image generated based on a first MR data set;

FIG. 11 is a flowchart illustrating an exemplary process for MRI according to some embodiments of the present disclosure;

FIG. 12 is a flowchart illustrating an exemplary process for generating a T1 weighted image according to some embodiments of the present disclosure;

FIG. 13 is a flowchart illustrating an exemplary process for MRI according to some embodiments of the present disclosure;

FIGS. 14A and 14B are flowcharts illustrating exemplary processes for determining a second signal representation of a subject according to some embodiments of the present disclosure;

FIG. 15 is a flowchart illustrating an exemplary process for MRI according to some embodiments of the present disclosure;

FIG. 16 is a flowchart illustrating an exemplary process for determining a value of a quantitative parameter according to some embodiments of the present disclosure;

FIGS. 17A-17D are schematic diagrams illustrating exemplary acquisition of a plurality of imaging data sets according to some embodiments of the present disclosure; and

FIGS. 18A-18C are schematic diagrams illustrating exemplary echoes in a TR according to some embodiments of the present disclosure.

### DETAILED DESCRIPTION

In the following detailed description, numerous specific details are set forth by way of examples in order to provide a thorough understanding of the relevant disclosure. However, it should be apparent to those skilled in the art that the present disclosure may be practiced without such details. In other instances, well-known methods, procedures, systems, components, and/or circuitry have been described at a relatively high-level, without detail, in order to avoid unnecessarily obscuring aspects of the present disclosure. Various modifications to the disclosed embodiments will be readily apparent to those skilled in the art, and the general principles defined herein may be applied to other embodiments and applications without departing from the spirit and scope of the present disclosure. Thus, the present disclosure is not limited to the embodiments shown, but to be accorded the widest scope consistent with the claims.

The terminology used herein is for the purpose of describing particular embodiments only and is not intended to be limiting of example embodiments of the invention. As used herein, the singular forms “a,” “an,” and “the,” are intended to include the plural forms as well, unless the context clearly indicates otherwise. As used herein, the terms “and/or” and “at least one of” include any and all combinations of one or more of the associated listed items. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof. Also, the term “exemplary” is intended to refer to an example or illustration.

It will be understood that the terms “system,” “engine,” “unit,” “module,” and/or “block” used herein are one method to distinguish different components, elements, parts, sections or assembly of different levels in ascending order. However, the terms may be displaced by another expression if they achieve the same purpose.

Generally, the word “module,” “unit,” or “block,” as used herein, refers to logic embodied in hardware or firmware, or to a collection of software instructions. A module, a unit, or a block described herein may be implemented as software and/or hardware and may be stored in any type of non-transitory computer-readable medium or another storage device. In some embodiments, a software module/unit/block may be compiled and linked into an executable program. It will be appreciated that software modules can be callable from other modules/units/blocks or from themselves, and/or may be invoked in response to detected events or interrupts. Software modules/units/blocks configured for execution on computing devices may be provided on a computer-readable medium, such as a compact disc, a digital video disc, a flash drive, a magnetic disc, or any other tangible medium, or as a digital download (and can be originally stored in a compressed or installable format that needs installation, decompression, or decryption prior to execution). Such software code may be stored, partially or fully, on a storage device of the executing computing device, for execution by the computing device. Software instructions may be embedded in firmware, such as an EPROM. It will be further appreciated that hardware modules/units/blocks may be included in connected logic components, such as gates and flip-flops, and/or can be included of programmable units, such as programmable gate arrays or processors. The modules/units/blocks or computing device functionality described herein may be implemented as software modules/units/blocks, but may be represented in hardware or firmware. In general, the modules/units/blocks described herein refer to logical modules/units/blocks that may be combined with other modules/units/blocks or divided into sub-modules/sub-units/sub-blocks despite their physical organization or storage. The description may be applicable to a system, an engine, or a portion thereof.

It will be understood that, although the terms “first,” “second,” “third,” etc., may be used herein to describe various elements, these elements should not be limited by these terms. These terms are only used to distinguish one element from another. For example, a first element could be termed a second element, and, similarly, a second element could be termed a first element, without departing from the scope of exemplary embodiments of the present disclosure.

The term “pixel” and “voxel” in the present disclosure are used interchangeably to refer to an element in an image. The term “image” in the present disclosure is used to refer to images of various forms, including a 2-dimensional image, a 3-dimensional image, a 4-dimensional image, etc.

Spatial and functional relationships between elements are described using various terms, including “connected,” “attached,” and “mounted.” Unless explicitly described as being “direct,” when a relationship between first and second elements is described in the present disclosure, that relationship includes a direct relationship where no other intervening elements are present between the first and second elements, and also an indirect relationship where one or more intervening elements are present (either spatially or functionally) between the first and second elements. In contrast, when an element is referred to as being “directly” connected, attached, or positioned to another element, there are no intervening elements present. Other words used to describe the relationship between elements should be interpreted in a like fashion (e.g., “between,” versus “directly between,” “adjacent,” versus “directly adjacent,” etc.).

These and other features, and characteristics of the present disclosure, as well as the methods of operation and functions of the related elements of structure and the combination of parts and economies of manufacture, may become more apparent upon consideration of the following description with reference to the accompanying drawings, all of which form a part of this disclosure. It is to be expressly understood, however, that the drawings are for the purpose of illustration and description only and are not intended to limit the scope of the present disclosure. It is understood that the drawings are not to scale.

These and other features, and characteristics of the present disclosure, as well as the methods of operation and functions of the related elements of structure and the combination of parts and economies of manufacture, may become more apparent upon consideration of the following description with reference to the accompanying drawings, all of which form a part of this disclosure. It is to be expressly understood, however, that the drawings are for the purpose of illustration and description only and are not intended to limit the scope of the present disclosure. It is understood that the drawings are not to scale.

The flowcharts used in the present disclosure illustrate operations that systems implement according to some embodiments of the present disclosure. It is to be expressly understood the operations of the flowcharts may be implemented not in order. Conversely, the operations may be implemented in inverted order, or simultaneously. Moreover, one or more other operations may be added to the flowcharts. One or more operations may be removed from the flowcharts.

Provided herein are systems and components for medical imaging and/or medical treatment. In some embodiments, the medical system may include an imaging system. The imaging system may include a single modality imaging system and/or a multi-modality imaging system. The single modality imaging system may include, for example, a magnetic resonance imaging (MRI) system. Exemplary MRI systems may include a superconducting magnetic resonance imaging system, a non-superconducting magnetic resonance imaging system, etc. The multi-modality imaging system may include, for example, a computed tomography-magnetic resonance imaging (MRI-CT) system, a positron emission tomography-magnetic resonance imaging (PET-MRI) system, a single photon emission computed tomography-magnetic resonance imaging (SPECT-MRI) system, a digital subtraction angiography-magnetic resonance imaging (DSA-MRI) system, etc. In some embodiments, the medical system may include a treatment system. The treatment system may include a treatment plan system (TPS), image-guide radiotherapy (IGRT), etc. The image-guide radiotherapy (IGRT) may include a treatment device and an imaging device. The treatment device may include a linear accelerator, a cyclotron, a synchrotron, etc., configured to perform a radio therapy on a subject. The treatment device may include an accelerator of species of particles including, for example, photons, electrons, protons, or heavy ions. The imaging device may include an MRI scanner, a CT scanner (e.g., cone beam computed tomography (CBCT) scanner), a digital radiology (DR) scanner, an electronic portal imaging device (EPID), etc.

An aspect of the present disclosure relates to systems and methods for T1 weighted dynamic imaging. The systems and methods may obtain a plurality of first magnetic resonance (MR) data sets related to a region of interest (ROI) of a subject. The plurality of first MR data sets may be collected based on two or more values of a scan parameter (e.g., a flip angle and/or a repetition time (TR)). The systems and methods may determine a plurality of second MR data sets based on the plurality of first MR data sets. Each of the plurality of second MR data sets may be determined based on at least two of the plurality of first MR data sets that correspond to two different values of the scan parameter. For example, for each of the plurality of second MR data sets, at least one first MR data set related to a first value of the scan parameter may be obtained. At least one first MR data set related to a second value of the scan parameter may be obtained. A division operation may be performed based on the at least two of the plurality of first MR data sets related to the first value and the second value of the scan parameter. The systems and methods may generate, based on the plurality of second MR data sets, a plurality of T1 weighted images of the ROI each of which corresponds to a target time point.

In the plurality of first MR data sets, besides T1 information, there are also non-T1 factors (e.g., related to equilibrium magnetization), such as T2*, a receiving coil sensitivity, an echo time (TE), a proton density of the ROI etc., which may introduce errors and biases to signal analysis, e.g., image reconstruction, physiological analysis, etc. The time between the middle of the excitation RF pulse and the peak of an echo may be called the echo time (TE) of the echo. The repetition time (TR) may be between two consecutive excitation RF pulses.

By determining a second MR data set by performing division between at least two of the plurality of first MR data sets, the one or more non-T1 factors in the at least two of the plurality of first MR data sets may be offset, so that the one or more factors non-T1 have less effect on the plurality of second MR data sets than the plurality of first MR data sets, thereby resulting a stronger contrast in the T1 weighted images, and making the subsequent physiological analysis more accurate. In addition, because the interference of non-T1 factors are eliminated or alleviated in the plurality of second MR data sets, the plurality of second MR data sets may be more sensitive to the T1 shortening effect caused by the contrast agent. So low-dose contrast agent can be used to reduce the cost and the potential impact of the contrast agent on the human body.

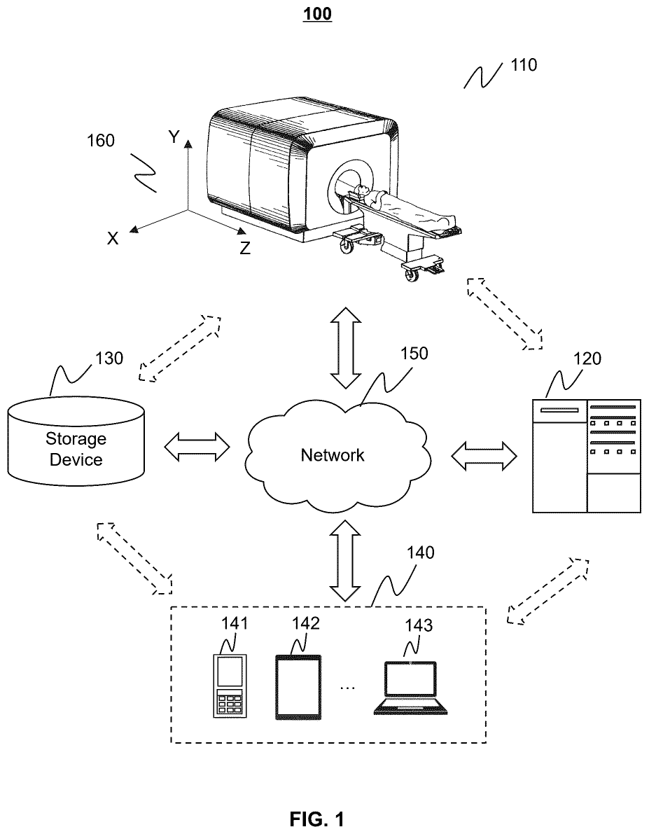

FIG. 1 is a schematic diagram illustrating an exemplary MRI system 100 according to some embodiments of the present disclosure. As illustrated, an MRI system 100 may include an MRI device 110, a processing device 120, a storage device 130, a terminal 140, and a network 150. The components of the MRI system 100 may be connected in one or more of various ways. Merely by way of example, as illustrated in FIG. 1, the MRI device 110 may be connected to the processing device 120 directly as indicated by the bi-directional arrow in dotted lines linking the MRI device 110 and the processing device 120, or through the network 150. As another example, the storage device 130 may be connected to the MRI device 110 directly as indicated by the bi-directional arrow in dotted lines linking the MRI device 110 and the storage device 130, or through the network 150. As still another example, the terminal 140 may be connected to the processing device 120 directly as indicated by the bi-directional arrow in dotted lines linking the terminal 140 and the processing device 120, or through the network 150.

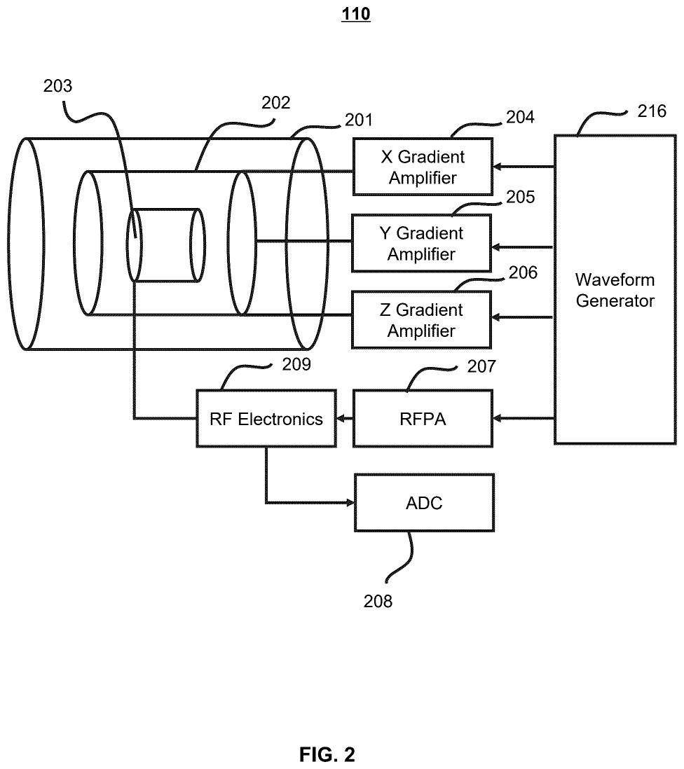

The MRI device 110 may be configured to scan a subject (or a part of the subject) to acquire image data, such as echo signals (also referred to as magnetic resonance (MR) data or MR signals) associated with the subject. For example, the MRI device 110 may detect a plurality of echo signals by applying an MRI pulse sequence on the subject. In some embodiments, the MRI device 110 may include, for example, a main magnet, a gradient coil (or also referred to as a spatial encoding coil), a radio frequency (RF) coil, etc., as described in connection with FIG. 2. In some embodiments, the MRI device 110 may be a permanent magnet MRI scanner, a superconducting electromagnet MRI scanner, a resistive electromagnet MRI scanner, etc., according to types of the main magnet. In some embodiments, the MRI device 110 may be a high-field MRI scanner, a mid-field MRI scanner, a low-field MRI scanner, etc., according to the intensity of the magnetic field.

The subject scanned by the MRI device 110 may be biological or non-biological. For example, the subject may include a patient, a man-made object, etc. As another example, the subject may include a specific portion, an organ, tissue, and/or a physical point of the patient. Merely by way of example, the subject may include the head, the brain, the neck, a body, a shoulder, an arm, the thorax, the heart, the stomach, a blood vessel, soft tissue, a knee, a foot, or the like, or any combination thereof.

For illustration purposes, a coordinate system 160 including an X-axis, a Y-axis, and a Z-axis may be provided in FIG. 1. The X-axis and the Z axis shown in FIG. 1 may be horizontal, and the Y-axis may be vertical. As illustrated, the positive X direction along the X-axis may be from the right side to the left side of the MRI device 110 seen from the direction facing the front of the MRI device 110; the positive Y direction along the Y-axis shown in FIG. 1 may be from the lower part to the upper part of the MRI device 110; the positive Z direction along the Z-axis shown in FIG. 1 may refer to a direction in which the subject is moved out of a detection region (or referred to as a bore) of the MRI device 110.

In some embodiments, the MRI device 110 may be directed to select an anatomical region (e.g., a slice or a volume) of the subject along a slice selection direction and scan the anatomical region to acquire a plurality of echo signals from the anatomical region. During the scan, spatial encoding within the anatomical region may be implemented by spatial encoding coils (e.g., an X coil, a Y coil, a Z coil) along a frequency encoding direction, a phase encoding direction, and a slice selection direction. The echo signals may be sampled and the corresponding sampled data may be stored into a k-space matrix for image reconstruction. For illustration purposes, the slice selection direction herein may correspond to the Z direction defined by the coordinate system 160 and a Kz direction in k-space; the phase encoding direction may correspond to the Y direction defined by the coordinate system 160 and a Ky direction in k-space; and the frequency encoding direction (also referred to as readout direction) may correspond to the X direction defined by the coordinate system 160 and a Kx direction in k-space. It should be noted that the slice selection direction, the phase encoding direction, and the frequency encoding direction may be modified according to actual needs, and the modification may do not depart the scope of the present disclosure. More description of the MRI device 110 may be found elsewhere in the present disclosure. See, e.g., FIG. 2 and the description thereof.

The processing device 120 may process data and/or information obtained from the MRI device 110, the storage device 130, and/or the terminal(s) 140. For example, the processing device 120 may obtain a plurality of first magnetic resonance (MR) data sets related to a region of interest (ROI) of a subject. The plurality of first MR data sets may be collected based on two or more values of a scan parameter. The processing device 120 may determine a plurality of second MR data sets based on the plurality of first MR data sets, each of the plurality of second MR data sets corresponding to at least two of the plurality of first MR data sets. The processing device 120 may generate, based on the plurality of second MR data sets, a plurality of T1 weighted images of the ROI each of which corresponds to a target time point. In some embodiments, the processing device 120 may be a single server or a server group. The server group may be centralized or distributed. In some embodiments, the processing device 120 may be local or remote. For example, the processing device 120 may access information and/or data from the MRI device 110, the storage device 130, and/or the terminal(s) 140 via the network 150. As another example, the processing device 120 may be directly connected to the MRI device 110, the terminal(s) 140, and/or the storage device 130 to access information and/or data. In some embodiments, the processing device 120 may be implemented on a cloud platform. For example, the cloud platform may include a private cloud, a public cloud, a hybrid cloud, a community cloud, a distributed cloud, an inter-cloud, a multi-cloud, or the like, or a combination thereof. In some embodiments, the processing device 120 may be part of the terminal 140. In some embodiments, the processing device 120 may be part of the MRI device 110.

The storage device 130 may store data, instructions, and/or any other information. In some embodiments, the storage device 130 may store data obtained from the MRI device 110, the processing device 120, and/or the terminal(s) 140. The data may include image data acquired by the processing device 120, algorithms and/or models for processing the image data, etc. For example, the storage device 130 may store a plurality of T1 weighted images determined by the processing device 120. In some embodiments, the storage device 130 may store data and/or instructions that the processing device 120 and/or the terminal 140 may execute or use to perform exemplary methods described in the present disclosure. In some embodiments, the storage device 130 may include a mass storage, removable storage, a volatile read-and-write memory, a read-only memory (ROM), or the like, or any combination thereof. Exemplary mass storage may include a magnetic disk, an optical disk, a solid-state drive, etc. Exemplary removable storage may include a flash drive, a floppy disk, an optical disk, a memory card, a zip disk, a magnetic tape, etc. Exemplary volatile read-and-write memories may include a random-access memory (RAM). Exemplary RAM may include a dynamic RAM (DRAM), a double date rate synchronous dynamic RAM (DDR SDRAM), a static RAM (SRAM), a thyristor RAM (T-RAM), and a zero-capacitor RAM (Z-RAM), etc. Exemplary ROM may include a mask ROM (MROM), a programmable ROM (PROM), an erasable programmable ROM (EPROM), an electrically erasable programmable ROM (EEPROM), a compact disk ROM (CD-ROM), and a digital versatile disk ROM, etc. In some embodiments, the storage device 130 may be implemented on a cloud platform. Merely by way of example, the cloud platform may include a private cloud, a public cloud, a hybrid cloud, a community cloud, a distributed cloud, an inter-cloud, a multi-cloud, or the like, or any combination thereof.

In some embodiments, the storage device 130 may be connected to the network 150 to communicate with one or more other components in the MRI system 100 (e.g., the processing device 120, the terminal(s) 140). One or more components in the MRI system 100 may access the data or instructions stored in the storage device 130 via the network 150. In some embodiments, the storage device 130 may be integrated into the MRI device 110 or the processing device 120.

The terminal(s) 140 may be connected to and/or communicate with the MRI device 110, the processing device 120, and/or the storage device 130. In some embodiments, the terminal 140 may include a mobile device 141, a tablet computer 142, a laptop computer 143, or the like, or any combination thereof. For example, the mobile device 141 may include a mobile phone, a personal digital assistant (PDA), a gaming device, a navigation device, a point of sale (POS) device, a laptop, a tablet computer, a desktop, or the like, or any combination thereof. In some embodiments, the terminal 140 may include an input device, an output device, etc. The input device may include alphanumeric and other keys that may be input via a keyboard, a touchscreen (for example, with haptics or tactile feedback), a speech input, an eye tracking input, a brain monitoring system, or any other comparable input mechanism. Other types of the input device may include a cursor control device, such as a mouse, a trackball, or cursor direction keys, etc. The output device may include a display, a printer, or the like, or any combination thereof.

The network 150 may include any suitable network that can facilitate the exchange of information and/or data for the MRI system 100. In some embodiments, one or more components of the MRI system 100 (e.g., the MRI device 110, the processing device 120, the storage device 130, the terminal(s) 140, etc.) may communicate information and/or data with one or more other components of the MRI system 100 via the network 150. For example, the processing device 120 may obtain a plurality of first magnetic resonance (MR) data sets related to a region of interest (ROI) of a subject from the MRI device 110 or the storage device 130 via the network 150. As another example, the processing device 120 and/or the terminal 140 may obtain information stored in the storage device 130 via the network 150. The network 150 may be and/or include a public network (e.g., the Internet), a private network (e.g., a local area network (LAN), a wide area network (WAN)), etc.), a wired network (e.g., an Ethernet network), a wireless network (e.g., an 802.11 network, a Wi-Fi network, etc.), a cellular network (e.g., a Long Term Evolution (LTE) network), a frame relay network, a virtual private network (VPN), a satellite network, a telephone network, routers, hubs, witches, server computers, and/or any combination thereof. For example, the network 150 may include a cable network, a wireline network, a fiber-optic network, a telecommunications network, an intranet, a wireless local area network (WLAN), a metropolitan area network (MAN), a public telephone switched network (PSTN), a Bluetooth™ network, a ZigBee™ network, a near field communication (NFC) network, or the like, or any combination thereof. In some embodiments, the network 150 may include one or more network access points. For example, the network 150 may include wired and/or wireless network access points such as base stations and/or internet exchange points through which one or more components of the MRI system 100 may be connected to the network 150 to exchange data and/or information.

This description is intended to be illustrative, and not to limit the scope of the present disclosure. Many alternatives, modifications, and variations will be apparent to those skilled in the art. The features, structures, methods, and other characteristics of the exemplary embodiments described herein may be combined in various ways to obtain additional and/or alternative exemplary embodiments. However, those variations and modifications do not depart the scope of the present disclosure. In some embodiments, the MRI system 100 may include one or more additional components and/or one or more components described above may be omitted. Additionally or alternatively, two or more components of the MRI system 100 may be integrated into a single component. For example, the processing device 120 may be integrated into the MRI device 110. As another example, a component of the MRI system 100 may be replaced by another component that can implement the functions of the component. As still another example, the processing device 120 and the terminal 140 may be integrated into a single device.

FIG. 2 is a schematic diagram illustrating an exemplary MRI device 110 according to some embodiments of the present disclosure. As illustrated, a main magnet 201 may generate a first magnetic field (or referred to as a main magnetic field) that may be applied to an object (also referred to as a subject) positioned inside the first magnetic field. The main magnet 201 may include a resistive magnet or a superconductive magnet that both need a power supply (not shown in FIG. 2) for operation. Alternatively, the main magnet 201 may include a permanent magnet. The main magnet 201 may form a detection region and surround, along the Z direction, the object that is moved into or positioned within the detection region. The main magnet 201 may also control the homogeneity of the generated main magnetic field. Some shim coils may be in the main magnet 201. The shim coils placed in the gap of the main magnet 201 may compensate for the inhomogeneity of the magnetic field of the main magnet 201. The shim coils may be energized by a shim power supply.

Gradient coils 202 may be located inside the main magnet 201. For example, the gradient coils 202 may be located in the detection region. The gradient coils 202 may surround, along the Z direction, the object that is moved into or positioned within the detection region. The gradient coils 202 may be surrounded by the main magnet 201 around the Z direction, and be closer to the object than the main magnet 201. The gradient coils 202 may generate a second magnetic field (or referred to as a gradient field, including gradient fields Gx, Gy, and Gz). The second magnetic field may be superimposed on the main magnetic field generated by the main magnet 201 and distort the main magnetic field so that the magnetic orientations of the protons of an object may vary as a function of their positions inside the gradient field, thereby encoding spatial information into MR signals generated by the region of the object being imaged. The gradient coils 202 may include X coils (e.g., configured to generate the gradient field Gx corresponding to the X direction), Y coils (e.g., configured to generate the gradient field Gy corresponding to the Y direction), and/or Z coils (e.g., configured to generate the gradient field Gz corresponding to the Z direction) (not shown in FIG. 2). In some embodiments, the Z coils may be designed based on circular (Maxwell) coils, while the X coils and the Y coils may be designed on the basis of the saddle (Golay) coil configuration. The three sets of coils may generate three different magnetic fields that are used for position encoding. The gradient coils 202 may allow spatial encoding of MR signals for image reconstruction. The gradient coils 202 may be connected with one or more of an X gradient amplifier 204, a Y gradient amplifier 205, or a Z gradient amplifier 206. One or more of the three amplifiers may be connected to a waveform generator 216. The waveform generator 216 may generate gradient waveforms that are applied to the X gradient amplifier 204, the Y gradient amplifier 205, and/or the Z gradient amplifier 206. An amplifier may amplify a waveform. An amplified waveform may be applied to one of the coils in the gradient coils 202 to generate a magnetic field in the X-axis, the Y-axis, or the Z-axis, respectively. The gradient coils 202 may be designed for either a close-bore MRI scanner or an open-bore MRI scanner. In some instances, all three sets of coils of the gradient coils 202 may be energized and three gradient fields may be generated thereby. In some embodiments of the present disclosure, the X coils and Y coils may be energized to generate the gradient fields in the X direction and the Y direction. As used herein, the X-axis, the Y-axis, the Z-axis, the X direction, the Y direction, and the Z direction in the description of FIG. 2 are the same as or similar to those described in FIG. 1.

In some embodiments, radio frequency (RF) coils 203 may be located inside the main magnet 201 and serve as transmitters, receivers, or both. For example, the RF coils 203 may be located in the detection region. The RF coils 203 may surround, along the Z direction, the object that is moved into or positioned within the detection region. The RF coils 203 may be surrounded by the main magnet 201 and/or the gradient coils 202 around the Z direction, and be closer to the object than the gradient coils 202. The RF coils 203 may be in connection with RF electronics 209 that may be configured or used as one or more integrated circuits (ICs) functioning as a waveform transmitter and/or a waveform receiver. The RF electronics 209 may be connected to a radiofrequency power amplifier (RFPA) 207 and an analog-to-digital converter (ADC) 208.

When used as transmitters, the RF coils 203 may generate RF signals that provide a third magnetic field that is utilized to generate MR signals related to the region of the object being imaged. The third magnetic field may be perpendicular to the main magnetic field. The waveform generator 216 may generate an RF pulse. The RF pulse may be amplified by the RFPA 207, processed by the RF electronics 209, and applied to the RF coils 203 to generate the RF signals in response to a powerful current generated by the RF electronics 209 based on the amplified RF pulse.

When used as receivers, the RF coils may be responsible for detecting MR signals (e.g., echoes). After excitation, the MR signals generated by the object may be sensed by the RF coils 203. The receive amplifier then may receive the sensed MR signals from the RF coils 203, amplify the sensed MR signals, and provide the amplified MR signals to the ADC 208. The ADC 208 may transform the MR signals from analog signals to digital signals. The digital MR signals then may be sent to the processing device 140 for sampling.

In some embodiments, the main magnet coil 201, the gradient coils 202, and the RF coils 203 may be circumferentially positioned with respect to the object around the Z direction. It is understood by those skilled in the art that the main magnet 201, the gradient coils 202, and the RF coils 203 may be situated in a variety of configurations around the object.

In some embodiments, the RFPA 207 may amplify an RF pulse (e.g., the power of the RF pulse, the voltage of the RF pulse) such that an amplified RF pulse is generated to drive the RF coils 203. The RFPA 207 may include a transistor-based RFPA, a vacuum tube-based RFPA, or the like, or any combination thereof. The transistor-based RFPA may include one or more transistors. The vacuum tube-based RFPA may include a triode, a tetrode, a klystron, or the like, or any combination thereof. In some embodiments, the RFPA 207 may include a linear RFPA, or a nonlinear RFPA. In some embodiments, the RFPA 207 may include one or more RFPAs.

In some embodiments, the MRI device 110 may further include a subject positioning system (not shown). The subject positioning system may include a subject cradle and a transport device. The subject may be placed on the subject cradle and be positioned by the transport device within the bore of the main magnet 201.

MRI systems (e.g., the MRI system 100 disclosed in the present disclosure) may be commonly used to obtain an interior image from a patient for a particular region of interest (ROI) that can be used for the purposes of, e.g., diagnosis, treatment, or the like, or a combination thereof. MRI systems include a main magnet (e.g., the main magnet 201) assembly for providing a main magnetic field to align the individual magnetic moments of the protons within the patient's body. During this process, the protons precess around their magnetic poles at their characteristic Larmor frequency. This state may be referred to as an equilibrium state. If the tissue is subjected to an additional magnetic field, which is tuned to the Larmor frequency, the protons absorb additional energy, which rotates the net aligned moment of the protons. This state may be referred to as an excitation state. The additional magnetic field may be provided by an RF excitation signal (e.g., the RF signal generated by the RF coils 203). When the additional magnetic field is removed, the magnetic moments of the protons rotate back into alignment with the main magnetic field thereby emitting an echo signal. The echo signal is received and processed to form an MRI image. T1 relaxation may be the process by which the net magnetization grows/returns to its initial maximum value parallel to the main magnetic field. T1 may be the time constant for regrowth of longitudinal magnetization (e.g., along the main magnetic field). T2 relaxation may be the process by which the transverse components of magnetization decay or dephase. T2 may be the time constant for decay/dephasing of transverse magnetization.

But in fact, the main magnetic field cannot achieve absolute uniformity. The rotation frequency of hydrogen atoms is related to the strength of the main magnetic field. The inhomogeneous main magnetic field may cause hydrogen atoms in different positions to rotate at different frequencies. Hydrogen atoms that locate in places with lower magnetic field strength may rotate more slowly. Hydrogen atoms that locate in places with higher magnetic field strength may rotate faster. Therefore, the rotation of hydrogen atoms may be out of sync, and the direction of their magnetization vectors may be more dispersed. The sum of these vectors may have a small amplitude, which accelerates the transverse magnetization decay. The time constant of the accelerated decay is T2*, which is smaller than T2.

If the main magnetic field is uniform across the entire body of the patient, then the RF excitation signal may excite all of the protons in the sample non-selectively. Accordingly, in order to image a particular portion of the patient's body, magnetic field gradients Gx, Gy, and Gz (e.g., generated by the gradient coils 202) in the X, Y, and Z directions, having a particular timing, frequency, and phase, may be superimposed on the uniform magnetic field such that the RF excitation signal excites the protons in a desired slice of the patient's body, and unique phase and frequency information is encoded in the echo signal depending on the location of the protons in the “image slice.” Based on a gradient encoding, a Fourier imaging may be performed, in which measurements representing the spatial frequency of the subject, termed as k-space, can be acquired using a specific sampling trajectory. The specific sampling trajectory may include a Cartesian trajectory or a non-Cartesian trajectory such as a spiral trajectory, a radial trajectory, etc., and an image reconstruction is performed by applying an inverse Fourier transform (e.g., inverse fast Fourier transform) on k-space data.

Typically, portions of the patient's body to be imaged are scanned by a sequence of measurement cycles in which the RF excitation signals and the magnetic field gradients Gx, Gy and Gz vary according to an MRI imaging protocol that is being used. A protocol may be designed for one or more tissues to be imaged, diseases, and/or clinical scenarios. A protocol may include a certain number of pulse sequences oriented in different planes and/or with different parameters. The pulse sequences may include spin echo sequences, gradient echo sequences, diffusion sequences, inversion recovery sequences, or the like, or any combination thereof. For instance, the spin echo sequences may include a fast spin echo (FSE) pulse sequence, a turbo spin echo (TSE) pulse sequence, a rapid acquisition with relaxation enhancement (RARE) pulse sequence, a half-Fourier acquisition single-shot turbo spin-echo (HASTE) pulse sequence, a turbo gradient spin echo (TGSE) pulse sequence, or the like, or any combination thereof. As another example, the gradient echo sequences may include a balanced steady-state free precession (bSSFP) pulse sequence, a spoiled gradient echo (GRE) pulse sequence, and an echo planar imaging (EPI) pulse sequence, a steady state free precession (SSFP), or the like, or any combination thereof. For each MRI scan, the resulting echo signals may be digitized and processed to reconstruct an image in accordance with the MRI imaging protocol that is used.

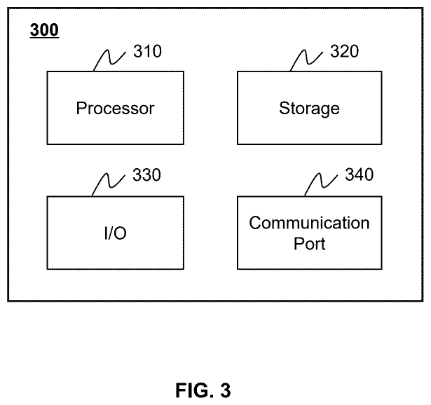

FIG. 3 is a schematic diagram illustrating exemplary hardware and/or software components of a computing device 300 according to some embodiments of the present disclosure. In some embodiments, one or more components of the MRI system 100 may be implemented on one or more components of the computing device 300. Merely by way of example, the processing device 120 may be implemented one or more components of the computing device 300.

As illustrated in FIG. 3, the computing device 300 may include a processor 310, a storage device 320, an input/output (I/O) 330, and a communication port 340. The processor 310 may execute computer instructions (e.g., program code) and perform functions of the processing device 120 in accordance with techniques described herein. The computer instructions may include, for example, routines, programs, objects, components, data structures, procedures, modules, and functions, which perform particular functions described herein. For example, the processor 310 may process image data of a subject obtained from the MRI device 110, the storage device 130, terminal(s) 140, and/or any other component of the MRI system 100.

In some embodiments, the processor 310 may include one or more hardware processors, such as a microcontroller, a microprocessor, a reduced instruction set computer (RISC), an application specific integrated circuits (ASICs), an application-specific instruction-set processor (ASIP), a central processing unit (CPU), a graphics processing unit (GPU), a physics processing unit (PPU), a microcontroller unit, a digital signal processor (DSP), a field programmable gate array (FPGA), an advanced RISC machine (ARM), a programmable logic device (PLD), any circuit or processor capable of executing one or more functions, or the like, or a combinations thereof.

Merely for illustration, only one processor is described in the computing device 300. However, it should be noted that the computing device 300 in the present disclosure may also include multiple processors. Thus operations and/or method steps that are performed by one processor as described in the present disclosure may also be jointly or separately performed by the multiple processors. For example, if in the present disclosure the processor of the computing device 300 executes both operation A and operation B, it should be understood that operation A and operation B may also be performed by two or more different processors jointly or separately in the computing device 300 (e.g., a first processor executes operation A and a second processor executes operation B, or the first and second processors jointly execute operations A and B).

The storage device 320 may store data/information obtained from the MRI device 110, the storage device 130, the terminal(s) 140, and/or any other component of the MRI system 100. In some embodiments, the storage device 320 may include a mass storage device, a removable storage device, a volatile read-and-write memory, a read-only memory (ROM), or the like, or any combination thereof. For example, the mass storage device may include a magnetic disk, an optical disk, a solid-state drive, etc. The removable storage device may include a flash drive, a floppy disk, an optical disk, a memory card, a zip disk, a magnetic tape, etc. The volatile read-and-write memory may include a random-access memory (RAM). The RAM may include a dynamic RAM (DRAM), a double date rate synchronous dynamic RAM (DDR SDRAM), a static RAM (SRAM), a thyristor RAM (T-RAM), and a zero-capacitor RAM (Z-RAM), etc. The ROM may include a mask ROM (MROM), a programmable ROM (PROM), an erasable programmable ROM (EPROM), an electrically erasable programmable ROM (EEPROM), a compact disk ROM (CD-ROM), and a digital versatile disk ROM, etc. In some embodiments, the storage device 320 may store one or more programs and/or instructions to perform exemplary methods described in the present disclosure.

The I/O 330 may input and/or output signals, data, information, etc. In some embodiments, the I/O 330 may enable a user interaction with the computing device 300 (e.g., the processing device 120). In some embodiments, the I/O 330 may include an input device and an output device. Examples of the input device may include a keyboard, a mouse, a touch screen, a microphone, or the like, or any combination thereof. Examples of the output device may include a display device, a loudspeaker, a printer, a projector, or the like, or any combination thereof. Examples of the display device may include a liquid crystal display (LCD), a light-emitting diode (LED)-based display, a flat panel display, a curved screen, a television device, a cathode ray tube (CRT), a touch screen, or the like, or any combination thereof.

The communication port 340 may be connected to a network (e.g., the network 150) to facilitate data communications. The communication port 340 may establish connections between the computing device 300 (e.g., the processing device 120) and one or more components of the MRI system 100 (e.g., the MRI device 110, the storage device 130, and/or the terminal(s) 140). The connection may be a wired connection, a wireless connection, any other communication connection that can enable data transmission and/or reception, and/or a combination of these connections. The wired connection may include, for example, an electrical cable, an optical cable, a telephone wire, or the like, or a combination thereof. The wireless connection may include, for example, a Bluetooth™ link, a Wi-Fi™ link, a WiMax™ link, a WLAN link, a ZigBee link, a mobile network link (e.g., 3G, 4G, 5G, etc.), or the like, or any combination thereof. In some embodiments, the communication port 340 may be and/or include a standardized communication port, such as RS232, RS485, etc. In some embodiments, the communication port 340 may be a specially designed communication port. For example, the communication port 340 may be designed in accordance with the digital imaging and communications in medicine (DICOM) protocol.

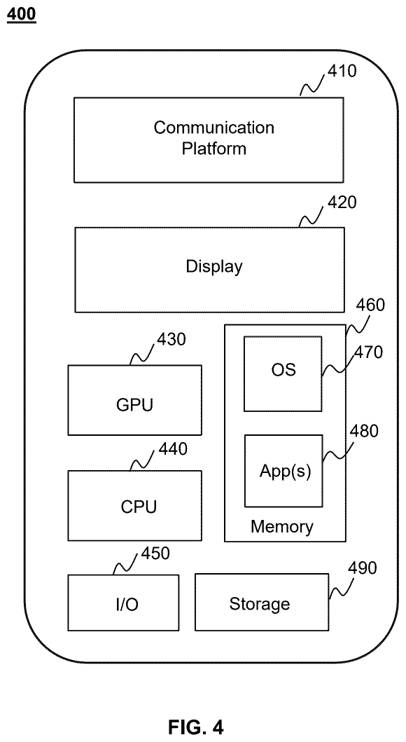

FIG. 4 is a schematic diagram illustrating exemplary hardware and/or software components of a mobile device 400 may be implemented according to some embodiments of the present disclosure. In some embodiments, one or more components of the MRI system 100 may be implemented on one or more components of the mobile device 400. Merely by way of example, the terminal 140 may be implemented on one or more components of the mobile device 400.

As illustrated in FIG. 4, the mobile device 400 may include a communication platform 410, a display 420, a graphics processing unit (GPU) 430, a central processing unit (CPU) 440, an 1/O 450, a memory 460, and a storage 490. In some embodiments, any other suitable component, including but not limited to a system bus or a controller (not shown), may also be included in the mobile device 400. In some embodiments, a mobile operating system 470 (e.g., iOS™, Android™, Windows Phone™, etc.) and one or more applications 480 may be loaded into the memory 460 from the storage 490 in order to be executed by the CPU 440. The applications 480 may include a browser or any other suitable mobile apps for receiving and rendering information relating to the MRI system 100. User interactions with the information stream may be achieved via the I/O 450 and provided to the processing device 120 and/or other components of the MRI system 100 via the network 150.

To implement various modules, units, and their functionalities described in the present disclosure, computer hardware platforms may be used as the hardware platform(s) for one or more of the elements described herein. A computer with user interface elements may be used to implement a personal computer (PC) or any other type of work station or terminal. A computer may also act as a server if appropriately programmed.

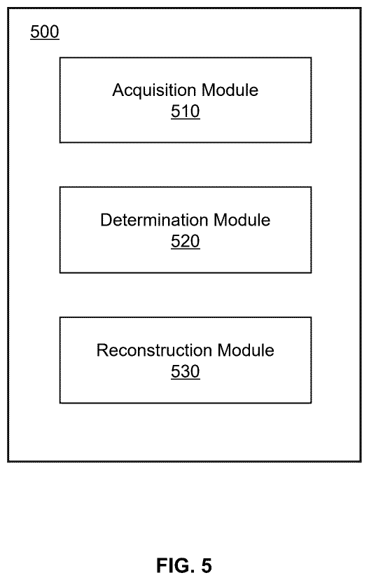

FIG. 5 is a schematic diagram illustrating an exemplary processing device 500 according to some embodiments of the present disclosure. In some embodiments, the processing device 120 may include an acquisition module 510, a determination module 520, and a reconstruction module 530. In some embodiments, the processing device 500 may be hardware circuits of all or part of the processing device 120. The processing device 500 may also be implemented as an application or set of instructions read and executed by the processing device 120. Further, the processing device 500 may be any combination of the hardware circuits and the application/instructions. For example, the modules may be part of the processing device 120 when the processing device 120 is executing the application/set of instructions.

The acquisition module 510 may obtain a plurality of first magnetic resonance (MR) data sets related to a region of interest (ROI) of a subject. The plurality of first MR data sets may be collected based on two or more different values of a scan parameter. The scan parameter may include at least one of a flip angle or a repetition time (TR).

The determination module 520 may determine a plurality of second MR data sets based on the plurality of first MR data sets. Each of the plurality of second MR data sets may correspond to at least two of the plurality of first MR data sets.

The reconstruction module 530 may generate, based on the plurality of second MR data sets, a plurality of T1 weighted images of the ROI each of which corresponds to a target time point.

In some embodiments, the reconstruction module 530 may perform T1 mapping based on the plurality of first MR data sets.

In some embodiments, the reconstruction module 530 may estimate a contrast agent concentration corresponding to each target time point based on the plurality of T1 weighted images and the T1 mapping. The reconstruction module 530 may perform physiological analysis of the ROI based on the contrast agent concentration corresponding to each target time point.

In some embodiments, the reconstruction module 530 may determine a signal intensity corresponding to each target time point based on the plurality of T1 weighted images. The reconstruction module 530 may perform physiological analysis of the ROI based on the signal intensity corresponding to each target time point.

It should be noted that the above description of the processing device 120 is merely provided for the purposes of illustration, and not intended to limit the scope of the present disclosure. For persons having ordinary skills in the art, multiple variations and modifications may be made under the teachings of the present disclosure. However, those variations and modifications do not depart from the scope of the present disclosure. Two or more of the modules may be combined as a single module, and any one of the modules may be divided into two or more units.

It should be noted that the above description is merely provided for the purposes of illustration, and not intended to limit the scope of the present disclosure. For persons having ordinary skills in the art, multiple variations and modifications may be made under the teachings of the present disclosure. However, those variations and modifications do not depart from the scope of the present disclosure. For example, the processing device 120 may further include a storage module (not shown in FIG. 5). The storage module may be configured to store data generated during any process performed by any component of in the processing device 120. As another example, each of the components of the processing device 120 may include a storage device. Additionally or alternatively, the components of the processing device 120 may share a common storage device.

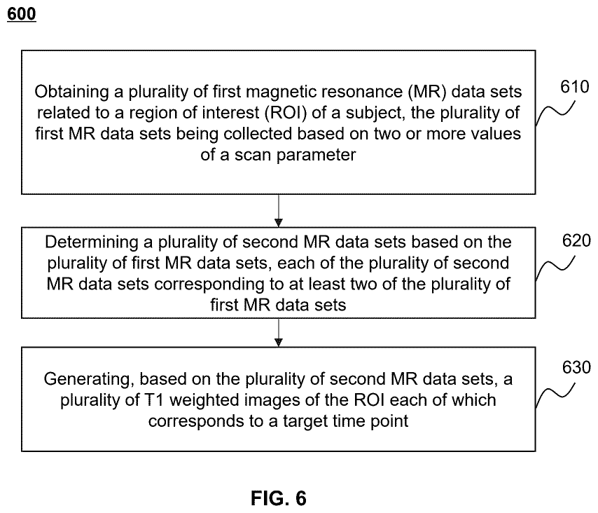

FIG. 6 is a flowchart illustrating an exemplary process 600 for generating a plurality of T1 weighted images according to some embodiments of the present disclosure. In some embodiments, the process 600 may be implemented in the MRI system 100 illustrated in FIG. 1. For example, the process 600 may be stored in the storage device 130 and/or the storage (e.g., the storage 320, the storage 490) as a form of instructions, and invoked and/or executed by the processing device 120 (e.g., the processor 310 of the computing device 300 as illustrated in FIG. 3, the CPU 440 of the mobile device 400 as illustrated in FIG. 4, or one or more modules illustrated in FIG. 5). The operations of the illustrated process presented below are intended to be illustrative. In some embodiments, the process 600 may be accomplished with one or more additional operations not described, and/or without one or more of the operations discussed. Additionally, the order in which the operations of the process 600 as illustrated in FIG. 6 and described below is not intended to be limiting.

In 610, the processing device 120 (e.g., the acquisition module 510) may obtain a plurality of first magnetic resonance (MR) data sets related to a region of interest (ROI) of a subject. The plurality of first MR data sets may be collected based on two or more different values of a scan parameter. The scan parameter may include at least one of a flip angle or a repetition time (TR).

In some embodiments, each of the plurality of first MR data sets may be acquired by applying a pulse sequence to the ROI. The pulse sequence may include a radiofrequency (RF) excitation pulse that is played out in the presence of a slice selection gradient in order to produce transverse magnetization in the ROI. In some embodiments, the RF excitation pulse may have a flip angle. As used herein, the flip angle may be the rotation of the net magnetization vector by the RF excitation pulse relative to the main magnetic field. The TR may be between two consecutive RF excitation pulses.

In some embodiments, the pulse sequence may be a steady-state sequence. A main magnet (e.g., the main magnet 201) assembly may provide a main magnetic field to align the individual magnetic moments of the protons within the ROI. This state may be referred to as an equilibrium state. When the ROI is subjected to an additional magnetic field, which is tuned to the Larmor frequency, the protons absorb additional energy, which rotates the net aligned moment of the protons. This state may be referred to as an excitation state. The additional magnetic field may be provided by an RF excitation signal (e.g., the RF signal generated by the RF coils 203). The process from the excitation state back to the equilibrium state may be referred to as a T1 relaxation. The steady-state sequence may refer to a pulse sequence that can exert repeated RF excitation to the protons and create a steadily repeatable combination of equilibrium state, excitation state and relaxation state. The steady-state sequence may include a spin echo (SE) sequence, a gradient echo (GRE) sequence, a magnetization preparation rapid gradient echo (IR-GRE) sequence, a magnetization preparation fast spin echo sequence, a gradient- and spin-echo (GRASE) sequence, etc.

The plurality of first MR data sets may include k-space data acquired by filling one or more echoes of the ROI received by a plurality of receiving coils (e.g., the RF coils 203) of an MRI device (e.g., the MRI device 110) into k-space along a sampling pattern.

In some embodiments, the ROI may include a slab or a volume of the subject for 3D imaging. In some embodiments, the ROI may include one or more slices of the subject for 2D imaging.

In some embodiments, the plurality of first MR data sets may include two-dimensional (2D) k-space data, three-dimensional (3D) k-space data, four-dimensional (4D) k-space data, or the like. As used herein, 4D k-space data refers to a data form containing 2D or 3D k-space data over time. Merely by way of example, the 3D k-space data may be a 256*256*256 digital matrix. In some embodiments, the plurality of first MR data sets may be undersampled, fully sampled, or oversampled.

In some embodiments, each of the plurality of first MR data sets may be acquired by completing k-space sampling in a temporally continuous manner-fer-ene-t #me. In some embodiments, the plurality of first MR data sets may be acquired in a temporally separated manner.

In some embodiments, each of the plurality of first MR data sets may be collected based on one of the two or more values of the scan parameter. Each of the plurality of first MR data sets may be collected using a pulse sequence with a flip angle and a TR. In some embodiments, the plurality of first MR data sets may be collected based on two or more values of flip angle and a same value of TR. For example, each of the plurality of first MR data sets may be collected based on one of the two or more values of flip angle and the same value of TR. In some embodiments, the plurality of first MR data sets may be collected based on two or more values of TR and a same value of flip angle. For example, each of the plurality of first MR data sets may be collected based on one of the two or more values of TR and the same value of flip angle. In some embodiments, the plurality of first MR data sets may be collected based on two or more values of flip angle and two or more values of TR. For example, each of the plurality of first MR data sets may be collected based on one of the two or more values of flip angle and one of the two or more values of TR.

In some embodiments, the two or more values of flip angle may be of any value. For example, for a first pulse sequence applied on the ROI, the value of flip angle may be greater than an Ernst angle (A_{E}=arccos(e^{-TR/T1})) corresponding to the TR of the first pulse sequence and T1 of the ROI. For a second pulse sequence applied on the ROI, the value of flip angle may be less than the Ernst angle corresponding to the TR of the second pulse sequence and T1 of the ROI. In some embodiments, the plurality of first MR data sets may be used for T1 weighted dynamic imaging, and the TR used to acquire the plurality of first MR data sets may be relatively short, e.g., shorter than 500 ms.

In some embodiments, the processing device 120 may obtain the plurality of first MR data sets from one or more components (e.g., the MRI device 110, the terminal 140, and/or the storage device 130) of the MRI system 100 or an external storage device via the network 150. For example, the MRI device 110 may transmit the plurality of first MR data sets to the storage device 130, or any other storage device for storage. The processing device 120 may obtain the plurality of first MR data sets from the storage device 130, or any other storage device. As another example, the processing device 120 may obtain the plurality of first MR data sets from the MRI device 110 directly.

In 620, the processing device 120 (e.g., the determination module 520) may determine a plurality of second MR data sets based on the plurality of first MR data sets. Each of the plurality of second MR data sets may correspond to at least two of the plurality of first MR data sets.

In some embodiments, the at least two of the plurality of first MR data sets corresponding to a second MR data set may correspond to two different values of the scan parameter. For example, the at least two of the plurality of first MR data sets corresponding to a second MR data set may correspond to two different values of flip angle. As another example, the at least two of the plurality of first MR data sets corresponding to a second MR data set may correspond to two different values of TR. As still another example, the at least two of the plurality of first MR data sets corresponding to a second MR data set may correspond to two different values of flip angle and two different values of TR.

In some embodiments, for one of the plurality of second MR data sets, the processing device 120 may obtain at least one first MR data set related to a first value of the scan parameter. The processing device 120 may obtain at least one first MR data set related to a second value of the scan parameter. The processing device 120 may perform division based on the at least two of the plurality of first MR data sets related to the first value and the second value of the scan parameter. For example, the processing device 120 may perform division between a first MR data set related to the first value and a first MR data set related to the second value of the scan parameter to determine the second MR data set. As another example, the processing device 120 may determine a first average of at least two first MR data sets related to the first value of the scan parameter, and a second average of at least two first MR data sets related to the second value of the scan parameter. The processing device 120 may perform division between the first average and the second average to determine the second MR data set. As still another example, the processing device 120 may determine an average of at least two first MR data sets related to the first value of the scan parameter. The processing device 120 may perform division between the average and a first MR data set related to the second value of the scan parameter to determine the second MR data set. As yet another example, the processing device 120 may determine an average of at least two first MR data sets related to the second value of the scan parameter. The processing device 120 may perform division between the average and a first MR data set related to the first value of the scan parameter to determine the second MR data set.

In some embodiments, the plurality of first MR data sets may be collected so that any two adjacent first MR data sets correspond to different values of the scan parameter. For each of the plurality of second MR data sets, the processing device 120 may determine the second MR data set based on two adjacent first MR data sets. For example, the processing device 120 may determine a second MR data set based on a division of two adjacent first MR data sets.

For example, the plurality of first MR data sets may be collected based on two or more different values of the flip angle and a fixed value of the TR; two or more different values of the TR and a fixed value of the flip angle; or two or more different values of the flip angle and two or more different values of the TR. The plurality of first MR data sets may be collected so that any two adjacent first MR data sets correspond to different values of at least one of the flip angle or the TR. For each of the plurality of second MR data sets, the processing device 120 may determine the second MR data set by performing division between two adjacent first MR data sets.

The second MR data set may correspond to a time point (e.g., an average time point) within a time period in which the two adjacent first MR data sets are acquired. For example, for two adjacent first MR data sets A and B in time order, the first MR data set A may be acquired during a time period t1 of which the start point is t, and the first MR data set B may be acquired during a time period t2. The time point related to a second MR data set corresponding to the two adjacent first MR data sets A and B may be t+(t1+t2)/2.

In some embodiments, at least one of the plurality of first MR data sets corresponding to a first value of the two or more value of the scan parameter may be collected before the rest of the plurality of first MR data sets corresponding to the rest of the two or more values of the scan parameter.

In some embodiments, the processing device 120 may determine an average of the at least one of the plurality of first MR data sets corresponding to the first value of the two or more value of the scan parameter. For each of the plurality of second MR data sets, the processing device 120 may determine the second MR data set based on the average and one of the rest of the plurality of first MR data sets. For example, the processing device 120 may determine a second MR data set based on a division of the average and one of the rest of the plurality of first MR data sets.

For example, the plurality of first MR data sets may be collected based on two or more different values of the flip angle and a fixed value of the TR; or two or more different values of the TR and a fixed value of the flip angle. At least one of the plurality of first MR data sets corresponding to a first value of the two or more values of the flip angle or the TR may be collected before the rest of the plurality of first MR data sets corresponding to the rest of the two or more values of the flip angle or the TR. As another example, the plurality of first MR data sets may be collected based on two or more different values of the flip angle and two or more different values of the TR. At least one of the plurality of first MR data sets corresponding to a first value of the two or more values of the flip angle and a first value of the two or more values of the TR may be collected before the rest of the plurality of first MR data sets corresponding to the rest of the two or more values of the flip angle and the rest of the two or more values of the TR. In the above two examples, the processing device 120 may determine an average of the at least one of the plurality of first MR data sets. For each of the plurality of second MR data sets, the processing device 120 may determine the second MR data set by performing division between the average and one of the rest of the plurality of first MR data sets.

In some embodiments, the second MR data set may correspond to a time point in a time period in which the one of the rest of the plurality of first MR data sets is acquired. For example, if the first MR data set is acquired based on Cartesian trajectory, the time point corresponding to the second MR data set may be the time when a phase encoding line (Ky=0) of the k-space center is sampled.

In some embodiments, the plurality of first MR data sets may be acquired based on an injection of a contrast agent into the ROI, e.g., the plurality of first MR data sets may be acquired based on dynamic contrast enhanced (DCE) imaging. In this case, at least one of the plurality of first MR data sets may be acquired before the injection of the contrast agent into the ROI, and the rest of the plurality of first MR data sets may be acquired after the injection of the contrast agent.

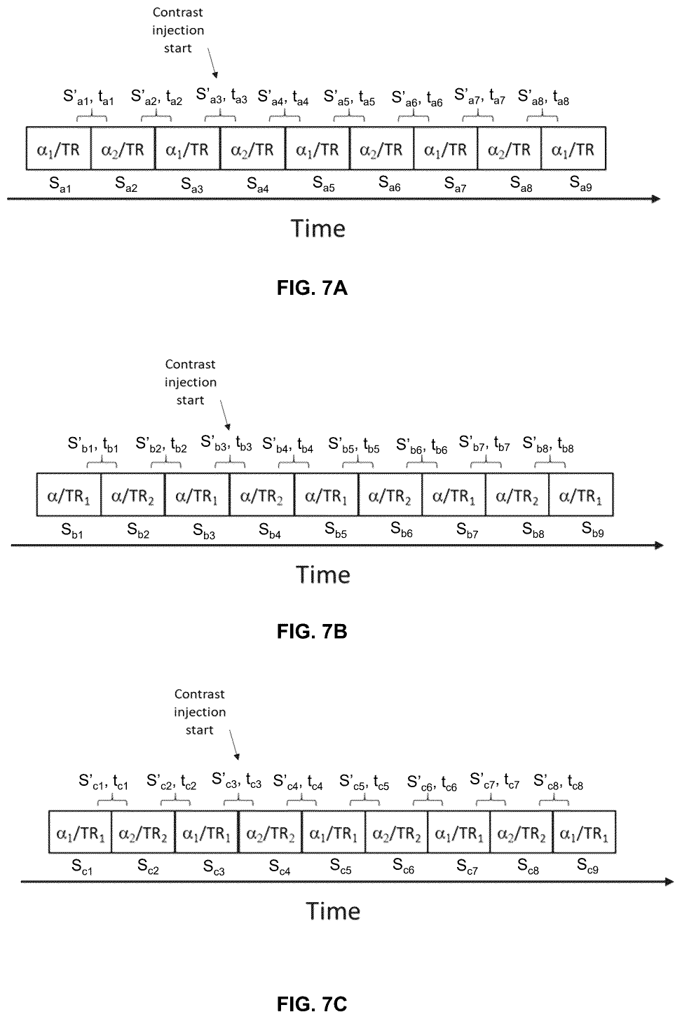

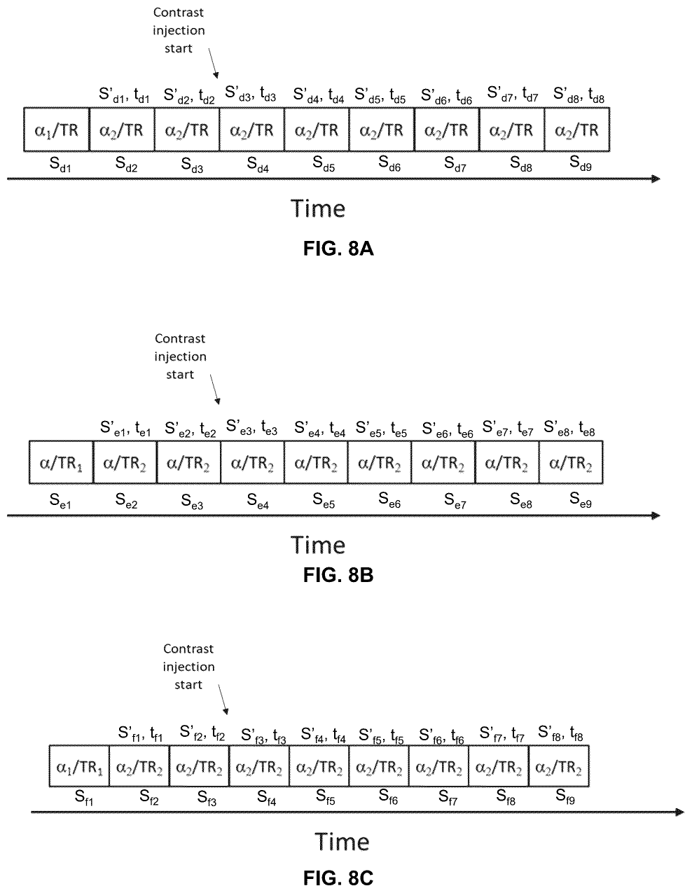

More Details regarding the determination of the plurality of second MR data sets may be found elsewhere in the present disclosure (e.g., the description in connection with FIGS. 7A-8C).

In 630, the processing device 120 (e.g., the reconstruction module 530) may generate, based on the plurality of second MR data sets, a plurality of T1 weighted images of the ROI each of which corresponds to a target time point. In some embodiments, a T1 weighted image of the ROI may include a 2D or 3D image. In some embodiments, each of the plurality of T1 weighted images may be generated by reconstructing one of the plurality of second MR data sets. The target time point of a T1 weighted image may be the time point corresponding to the second MR data set used to generate the T1 weighted image.

In some embodiments, the processing device 120 may generate, based on the plurality of second MR data sets, the plurality of T1 weighted images using any reconstruction algorithm, such as parallel imaging (PI), multi-band (MB) imaging, compress sensing (CS), artificial intelligence (AI) reconstruction, or the like, or any combination thereof.

In some embodiments, the processing device 120 may determine a signal intensity corresponding to each target time point based on the plurality of T1 weighted images. In some embodiments, the pixel values (e.g., gray values) may be related to (for example, linear relation) the signal intensity, and the signal intensity corresponding to each T1 weighted image may be determined based on the pixel values of the T1 weighted image. For example, the processing device 120 may determine an average of pixel values of all pixels in a T1 weighted image, and specify the average as the signal intensity (e.g., an average signal intensity) of the T1 weighted image. For another example, the processing device 120 may identify one or more regions in a T1 weighted image. The processing device 120 may determine an average of pixel values of the pixels in the one or more regions, and specify the average as the signal intensity (e.g., an average signal intensity) of the T1 weighted image. Then, according to the signal intensity and target time point corresponding to each T1 weighted image, the processing device 120 may generate an intensity-time curve.

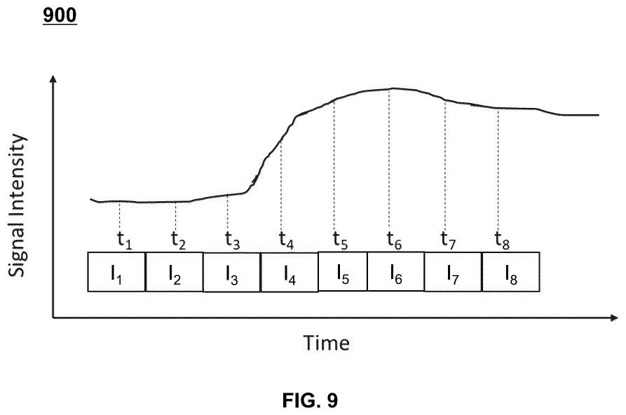

FIG. 9 is a schematic diagram illustrating an exemplary intensity-time curve 900 according to some embodiments of the present disclosure.

As shown in FIG. 9, the processing device 120 may generate, based on the process 600, a plurality of T1 weighted images I₁-I₈ corresponding to target time points t₁-t₈, respectively. The processing device 120 may determine a signal intensity corresponding to each target time point based on the plurality of T1 weighted images, and determine the intensity-time curve 900 based on the signal intensities corresponding to the target time points t₁-t₈.

In some embodiments, the processing device 120 may perform physiological analysis based on the signal intensity corresponding to each target time point. For example, the processing device 120 may perform physiological analysis based on the intensity-time curve.

To perform physiological analysis, imaging of contrast agent uptake within the ROI may be performed. In some embodiments, dynamic contrast enhanced imaging may be applied for physiological analysis.

DCE imaging is an imaging technique that uses characteristics of tissue blood vessels. DCE imaging can provide information about the characteristics of physiological tissues. In DCE imaging, a contrast agent is usually injected into the patient's body, and T1 weighted magnetic resonance images before and after the injection of the contrast agent are collected. Due to the permeability of the capillaries, the surface area of the blood vessels and the blood flow velocity are different, the diffusion speed of the contrast agent is different. There are differences between different organizations, thus forming a contrast in the images. Methods used for DCE data analysis mainly include semi-quantitative and quantitative. Semi-quantitative analysis is based on intensity-time curve analysis to obtain characteristics such as tissue perfusion, capillary surface area, capillary permeability, and extravascular-extracellular space (EES). Exemplary semi-quantitative analysis parameters may include onset time, time to peak, maximum signal intensity, etc., which describe the shape and the composition of the intensity-time curve. Quantitative analysis may determine the contrast agent concentration in the ROI, and then analyze the characteristics of tissue perfusion, capillary surface area, capillary permeability, and extravascular-extracellular space (EES). Simple quantitative parameters may include the initial area under the curve. Quantitative analysis can also fit multiple pharmacokinetic models to mathematically analyze and determine the intensity-time curve.

In some embodiments, the processing device 120 may perform T1 mapping based on the plurality of first MR data sets. In some embodiments, if the plurality of first MR data sets are collected based on two or more values of flip angle (as shown in FIG. 7A and FIG. 8A) or two or more values of TR (as shown in FIG. 7B and FIG. 8B), the processing device 120 may perform T1 mapping based on the plurality of first MR data sets; if the plurality of first MR data sets are collected based on two or more values of flip angle and two or more values of TR (as shown in FIG. 7C and FIG. 8C), T1 mapping cannot be achieved based on the plurality of first MR data sets.

In some embodiments, the processing device 120 may perform T1 mapping using any suitable algorithm. For example, the processing device 120 may perform T1 mapping based on Equation (1) below:

$$\frac{S ( α , TR )}{sin ( α )} = \frac{S ( α , TR )}{tan ( α )} E + ρ ( 1 - E ) , \qquad ( 1 )$$

wherein ρ refers to a coefficient related to longitudinal magnetization; S(α, TR) refers to a first MR data set acquired based on a flip angle α and a TR; and E=e^{-TR/T1}.

Equation (1) may be regarded as a linear equation between

$$\frac{S ( α , TR )}{sin ( α )} and \frac{S ( α , TR )}{tan ( α )} .$$

The processing device 120 may determine the slope E and the intercept ρ(1−E) based on at least two of the plurality of first MR data sets, thereby determining a T1 value for each pixel or voxel and achieving T1 mapping, e.g., generating a quantitative T1 map.

In some embodiments, the processing device 120 may estimate a contrast agent concentration corresponding to each target time point based on the plurality of T1 weighted images and the T1 mapping. The processing device 120 may estimate the contrast agent concentration corresponding to each target time point based on the plurality of T1 weighted images and the T1 mapping using any suitable algorithm.

The processing device 120 may perform physiological analysis (e.g., DCE analysis) based on the contrast agent concentration corresponding to each target time point. For example, the processing device 120 may determine a concentration-time curve based on the contrast agent concentration corresponding to the target time points, and perform physiological analysis (e.g., DCE analysis) based on the concentration-time curve.

It should be noted that the above description regarding the process 600 is merely provided for the purposes of illustration, and not intended to limit the scope of the present disclosure. For persons having ordinary skills in the art, multiple variations and modifications may be made under the teachings of the present disclosure. However, those variations and modifications do not depart from the scope of the present disclosure. In some embodiments, the process 600 may be accomplished with one or more additional operations not described and/or without one or more of the operations discussed above. In some embodiments, the Equations provided above are illustrative examples and can be modified in various ways. For example, one or more coefficients in an Equation may be omitted, and/or the Equation may further include one or more additional coefficients.

FIGS. 7A-7C are schematic diagrams illustrating exemplary acquisition of a plurality of first MR data sets according to some embodiments of the present disclosure.

As shown in FIG. 7A, the processing device 120 may obtain a plurality of first MR data sets Sₐ₁-Sₐ₉. Sₐ₁-Sₐ₉ may be acquired in chronological order. Sₐ₁-Sₐ₉ may be acquired based on two different flip angles (α₁ and α₂) and the same TR. Each of Sₐ₁-Sₐ₉ may correspond to the same TR and one of α₁ and α₂. Sₐ₁-Sₐ₉ may be collected so that any two adjacent first MR data sets correspond to different values of flip angle. For example, as shown in FIG. 7A, α₁ and α₂ may be applied alternately to acquire Sₐ₁-Sₐ₉.

The processing device 120 may determine a second MR data set based on two adjacent first MR data sets. As shown in FIG. 7A, the processing device 120 may determine a division of Sₐ₁ and Sₐ₂ to determine a second MR data set S′ₐ₁. S′ₐ₁ may correspond to a time point tₐ₁ (e.g., an average time point) within a time period in which Sₐ₁ and Sₐ₂ are acquired. The processing device 120 may determine a division of Sₐ₂ and Sₐ₃ to determine a second MR data set S′ₐ₂. S′ₐ₂ may correspond to a time point tₐ₂ (e.g., an average time point) within a time period in which Sₐ₂ and Sₐ₃ are acquired. The processing device 120 may determine a division of Sₐ₃ and Sₐ₄ to determine a second MR data set S′ₐ₃. S′ₐ₃ may correspond to a time point tₐ₃ (e.g., an average time point) within a time period in which Sₐ₃ and Sₐ₄ are acquired. The processing device 120 may determine a division of Sₐ₄ and Sₐ₅ to determine a second MR data set S′ₐ₄. S′ₐ₄ may correspond to a time point tₐ₄ (e.g., an average time point) within a time period in which Sₐ₄ and Sₐ₅ are acquired. The processing device 120 may determine a division of Sₐ₅ and Sₐ₆ to determine a second MR data set S′ₐ₅. S′ₐ₅ may correspond to a time point tₐ₅ (e.g., an average time point) within a time period in which Sₐ₅ and Sₐ₆ are acquired. The processing device 120 may determine a division of Sₐ₆ and Sₐ₇ to determine a second MR data set S′ₐ₆. S′ₐ₆ may correspond to a time point tₐ₆ (e.g., an average time point) within a time period in which Sₐ₆ and Sₐ₇ are acquired. The processing device 120 may determine a division of Sₐ₇ and Sₐ₈ to determine a second MR data set S′ₐ₇. S′ₐ₇ may correspond to a time point tₐ₇ (e.g., an average time point) within a time period in which Sₐ₇ and Sₐ₈ are acquired. The processing device 120 may determine a division of Sₐ₈ and Sₐ₉ to determine a second MR data set S′ₐ₈. S′ₐ₈ may correspond to a time point tₐ₈ (e.g., an average time point) within a time period in which Sₐ₈ and Sag are acquired.

In some embodiments, a first MR data set acquired based on a flip angle a and a TR may be represented based on Equation (2) below:

$$S ( α , TR ) = {M}_{0} \frac{( 1 - E ) sin ( α )}{1 - E cos ( α )} , \qquad ( 2 )$$

wherein S(α, TR) refers to a first MR data set acquired based on a flip angle a and a TR; E=e^{-TR/T1}; and M₀ is the base signal that includes one or more non-T1 factors (e.g., related to equilibrium magnetization) of the ROI. The one or more non-T1 factors may depend on the configuration of the MRI device 110 and tissue properties of the ROI. For example, the one or more non-T1 factors may include T2*, a receiving coil sensitivity, an echo time (TE), a proton density of the ROI, or the like, or any combination thereof. Merely by way of example, M₀=CØe^{-TE/T2*}, wherein C refers to the receiving coil sensitivity, and Ø refers to the proton density.

Taking the second MR data set S′ₐ₁ as an example, the processing device 120 may determine S′ₐ₁ based on Equation (3) below:

$${S}_{a 1}^{′} = \frac{{s}_{a 2} ( {α}_{2} , TR )}{{s}_{a 1} ( {α}_{1} , TR )} = \frac{sin ( {α}_{2} )}{sin ( {α}_{1} )} \cdot \frac{1 - E cos ( {α}_{1} )}{1 - E cos ( {α}_{2} )} . \qquad ( 3 )$$

In some embodiments, to determine the second MR data set S′ₐ₁, there is no limit of the order of the division of the adjacent first MR data sets Sₐ₁ and Sₐ₂. The processing device 120 may also determine S′ₐ₁ based on Equation (4) below:

$${S}_{a 1}^{′} = \frac{{s}_{a 1} ( {α}_{1} , TR )}{{s}_{a 2} ( {α}_{2} , TR )} = \frac{sin ( {α}_{1} )}{sin ( {α}_{2} )} \cdot \frac{1 - E cos ( {α}_{2} )}{1 - E cos ( {α}_{1} )} . \qquad ( 4 )$$

S′ₐ₂-S′ₐ₈ may be determined based on an approach similar to Equation (3) or Equation (4).

It should be noted that the above description is merely provided for the purposes of illustration, and not intended to limit the scope of the present disclosure. For persons having ordinary skills in the art, multiple variations and modifications may be made under the teachings of the present disclosure. However, those variations and modifications do not depart from the scope of the present disclosure.

As shown in FIG. 7B, the processing device 120 may obtain a plurality of first MR data sets S_{b1}-S_{b9}. S_{b1}-S_{b9} may be acquired in chronological order. S_{b1}-S_{b9} may be acquired based on two different values of TR (TR₁ and TR₂) and the same flip angle a. Each of S_{b1}-S_{b9} may correspond to the same flip angle a and one of TR₁ and TR₂. S_{b1}-S_{b9} may be collected so that any two adjacent first MR data sets correspond to different values of TR. For example, as shown in FIG. 7B, TR₁ and TR₂ may be applied alternately to acquire S_{b1}-S_{b9}.

The processing device 120 may determine a second MR data set based on two adjacent first MR data sets. As shown in FIG. 7B, the processing device 120 may determine a division of S_{b1} and S_{b2} to determine a second MR data set S′_{b1}. S′_{b1} may correspond to a time point t_{b1} (e.g., an average time point) within a time period in which S_{b1} and S_{b2} are acquired. The processing device 120 may determine a division of S_{b2} and S_{b3} to determine a second MR data set S′_{b2}. S′_{b2} may correspond to a time point t_{b2} (e.g., an average time point) within a time period in which S_{b2} and S_{b3} are acquired. The processing device 120 may determine a division of S_{b3} and S_{b4} to determine a second MR data set S′_{b3}. S′_{b3} may correspond to a time point t_{b3} (e.g., an average time point) within a time period in which S_{b3} and S_{b4} are acquired. The processing device 120 may determine a division of S_{b4} and S_{b5} to determine a second MR data set S′_{b4}. S′_{b4} may correspond to a time point t_{b4} (e.g., an average time point) within a time period in which S_{b4} and S_{b5} are acquired. The processing device 120 may determine a division of S_{b5} and S_{b6} to determine a second MR data set S′_{b5}. S′_{b5} may correspond to a time point t_{b5} (e.g., an average time point) within a time period in which S_{b5} and S_{b6} are acquired. The processing device 120 may determine a division of S_{b6} and S_{b7} to determine a second MR data set S′_{b6}. S′_{b6} may correspond to a time point t_{b6} (e.g., an average time point) within a time period in which S_{b6} and S_{b7} are acquired. The processing device 120 may determine a division of S_{b7} and S_{b8} to determine a second MR data set S′_{b7}. S′_{b7} may correspond to a time point t_{b7} (e.g., an average time point) within a time period in which S_{b7} and S_{b8} are acquired. The processing device 120 may determine a division of S_{b8} and S_{b9} to determine a second MR data set S′_{b8}. S′_{b8} may correspond to a time point t_{b}s (e.g., an average time point) within a time period in which S_{b8} and S_{b9} are acquired.

Taking the second MR data set S′_{b1} as an example, the processing device 120 may determine S′_{b1} based on Equation (5) below:

$${S}_{b 1}^{′} = \frac{{s}_{b 2} ( α , TR )}{{s}_{b 1} ( α , TR )} = \frac{1 - {E}_{2}}{1 - {E}_{1}} \cdot \frac{1 - {E}_{1} cos ( α )}{1 - {E}_{2} cos ( α )} , \qquad ( 5 )$$

wherein E₁=e^{-TR}^{₁}^{/T1}, E₂=e^{-TR}^{₂}^{/T1}.

In some embodiments, to determine the second MR data set S′_{b1}, there is no limit of the order of the division of the adjacent first MR data sets S_{b1} and S_{b2}. The processing device 120 may also determine S′_{b1} based on Equation (6) below:

$${S}_{b 1}^{′} = \frac{{s}_{b 1} ( α , {TR}_{1} )}{{s}_{b 2} ( α , {TR}_{2} )} = \frac{1 - {E}_{1}}{1 - {E}_{2}} \cdot \frac{1 - {E}_{2} cos ( α )}{1 - {E}_{1} cos ( α )} . \qquad ( 6 )$$

S′_{b2}-S′_{b8} may be determined based on an approach similar to Equation (5) or Equation (6).

It should be noted that the above description is merely provided for the purposes of illustration, and not intended to limit the scope of the present disclosure. For persons having ordinary skills in the art, multiple variations and modifications may be made under the teachings of the present disclosure. However, those variations and modifications do not depart from the scope of the present disclosure.

As shown in FIG. 7C, the processing device 120 may obtain a plurality of first MR data sets S_{c1}-S_{c9}. S_{c1}-S_{c9} may be acquired in chronological order. S_{c1}-S_{c9} may be acquired based on two different values of TR (TR₁ and TR₂) and two different values of flip angle (α₁ and α₂). Each of S_{c1}-S_{c9} may correspond to one of α₁ and α₂ and one of TR₁ and TR₂. S_{c1}-S_{c9} may be collected so that any two adjacent first MR data sets correspond to different values of TR and different values of flip angle.

For example, as shown in FIG. 7C, to acquire S_{c1}-S_{c9}, TR₁ and TR₂ may be applied alternately, and α₁ and α₂ may be applied alternately. For example, as shown in FIG. 7C, Sci may correspond to α₁ and TR₁, S_{c2} may correspond to α₂ and TR₂, and so on. As another example, S_{c1} may correspond to α₁ and TR₂, S_{c2} may correspond to α₂ and TR₁, and so on.

The processing device 120 may determine a second MR data set based on two adjacent first MR data sets. As shown in FIG. 7C, the processing device 120 may determine a division of S_{c1} and S_{c2} to determine a second MR data set S′_{c1}. S′_{c1} may correspond to a time point t_{c1} (e.g., an average time point) within a time period in which S_{c1} and S_{c2} are acquired. The processing device 120 may determine a division of S_{c2} and S_{c3} to determine a second MR data set S′_{c2}. S′_{c2} may correspond to a time point t_{c2} (e.g., an average time point) within a time period in which S_{c2} and S_{c3} are acquired. The processing device 120 may determine a division of S_{c3} and S_{c4} to determine a second MR data set S′_{c3}. S′_{c3} may correspond to a time point t_{c3} (e.g., an average time point) within a time period in which S_{c3} and S_{c4} are acquired. The processing device 120 may determine a division of S_{c4} and S_{c5} to determine a second MR data set S′_{c4}. S′_{c4} may correspond to a time point t_{c4} (e.g., an average time point) within a time period in which S_{c4} and S_{c5} are acquired. The processing device 120 may determine a division of S_{c5} and S_{c6} to determine a second MR data set S′_{c5}. S′_{c5} s may correspond to a time point t_{c5} (e.g., an average time point) within a time period in which S_{c5} and S_{c6} are acquired. The processing device 120 may determine a division of S_{c6} and S_{c7} to determine a second MR data set S′_{c6}. S′_{c6} may correspond to a time point t_{c6} (e.g., an average time point) within a time period in which S_{c6} and S_{c7} are acquired. The processing device 120 may determine a division of S_{c7} and S_{c8} to determine a second MR data set S′_{c7}. S′_{c7} may correspond to a time point t_{c7} (e.g., an average time point) within a time period in which S_{c7} and Sc are acquired. The processing device 120 may determine a division of S_{c8} and S_{c9} to determine a second MR data set S′_{c8}. S′_{c8} may correspond to a time point t_{c8} (e.g., an average time point) within a time period in which S_{c8} and S_{c9} are acquired.

Taking the second MR data set S′_{c1} as an example, the processing device 120 may determine S′_{c1} based on Equation (7) below:

$${S}_{c 1}^{′} = \frac{{s}_{c 1} ( {α}_{2} , {TR}_{2} )}{{s}_{c 2} ( {α}_{1} , {TR}_{1} )} = \frac{sin ( {α}_{2} )}{sin ( {α}_{1} )} \cdot \frac{1 - {E}_{2}}{1 - {E}_{1}} \cdot \frac{1 - {E}_{1} cos ( {α}_{1} )}{1 - {E}_{2} cos ( {α}_{2} )} . \qquad ( 7 )$$

In some embodiments, to determine the second MR data set S′_{c1}, there is no limit of the order of the division of the adjacent first MR data sets S_{c1} and S_{c2}. The processing device 120 may also determine S′_{c1} based on Equation (8) below:

$${S}_{c 1}^{′} = \frac{{s}_{c 1} ( {α}_{1} , {TR}_{1} )}{{s}_{c 2} ( {α}_{2} , {TR}_{2} )} = \frac{sin ( {α}_{1} )}{sin ( {α}_{2} )} \cdot \frac{1 - {E}_{1}}{1 - {E}_{2}} \cdot \frac{1 - {E}_{2} cos ( {α}_{2} )}{1 - {E}_{1} cos ( {α}_{1} )} . \qquad ( 8 )$$

S′_{c2}-S′_{c8} may be determined based on an approach similar to Equation (7) or Equation (8).

It should be noted that the above description is merely provided for the purposes of illustration, and not intended to limit the scope of the present disclosure. For persons having ordinary skills in the art, multiple variations and modifications may be made under the teachings of the present disclosure. However, those variations and modifications do not depart from the scope of the present disclosure.

FIGS. 8A-8C are schematic diagrams illustrating exemplary acquisition of a plurality of first MR data sets according to some embodiments of the present disclosure.

As shown in FIG. 8A, the processing device 120 may obtain a plurality of first MR data sets S_{d1}-S_{d9}. S_{d1}-S_{d9} may be acquired in chronological order. S_{d1}-S_{d9} may be acquired based on two different flip angles (α₁ and α₂) and the same TR. Each of S_{d1}-S_{d9} may correspond to the same TR and one of α₁ and α₂. S_{d1} corresponding to α₁ may be acquired before S_{d2}-S_{d9} corresponding to α₂.

As shown in FIG. 8A, the processing device 120 may determine a division of S_{d1} and S_{d2} to determine a second MR data set S′_{d1}. S′_{d1} may correspond to a time point t_{d1} within a time period in which S_{d2} is acquired. The processing device 120 may determine a division of S_{d1} and S_{d2} to determine a second MR data set S′_{d2}. S′_{d2} may correspond to a time point t_{d2} within a time period in which S_{d3} is acquired. The processing device 120 may determine a division of S_{d1} and S_{d4} to determine a second MR data set S′_{d3}. S′_{d3} may correspond to a time point t_{d3} within a time period in which S_{d4} is acquired. The processing device 120 may determine a division of S_{d1} and S_{d5} to determine a second MR data set S′_{d4}. S′_{d4} may correspond to a time point t_{d4} within a time period in which S_{d}s is acquired. The processing device 120 may determine a division of S_{d1} and S_{d6} to determine a second MR data set S′_{d5}. S′_{d5} may correspond to a time point t_{d5} within a time period in which S_{d6} is acquired. The processing device 120 may determine a division of S_{d1} and S_{d7} to determine a second MR data set S′_{d6}. S′_{d6} may correspond to a time point t_{d6} within a time period in which S_{d7} is acquired. The processing device 120 may determine a division of S_{d1} and S_{d6} to determine a second MR data set S′_{d7}. S′_{d7} may correspond to a time point t_{d7} within a time period in which S_{d8} is acquired. The processing device 120 may determine a division of S_{d1} and Sd to determine a second MR data set S′_{d8}. S′_{d8} may correspond to a time point t_{d8} within a time period in which S_{d9} is acquired.

Taking the second MR data set S′_{d1} as an example, the processing device 120 may determine S′_{d1} based on Equation (9) below:

$${S}_{d 1}^{′} = \frac{{S}_{d 2} ( {α}_{2} , TR )}{\overline{S ( {α}_{1} , TR )}} , \qquad ( 9 )$$

wherein S̅(̅α̅₁̅,̅T̅R̅)̅ refers to an average of the first MR data sets corresponding to α₁. If there is only one first MR data set corresponding to α₁ (S_{d1} shown in FIG. 8A), S̅(̅α̅₁̅,̅ T̅R̅)̅=S_{d1}(α₁, TR). If there is two or more first MR data sets corresponding to α₁, e.g., represented as S_{d11}(α₁,TR), S_{d12}(α₁,TR), . . . , S_{d1n}(α₁, TR), S̅(̅α̅₁̅,̅ T̅R̅)̅=[S_{d11}(α₁, TR)+S_{d12}(α₁, TR)+ . . . +S_{d1n}(α₁, TR)]/n (n is an integer that is greater than 1). In some embodiments, to determine the second MR data set S′_{d1}, there is no limit of the order of the division of S̅(̅α̅₁̅,̅ T̅R̅)̅ and S_{d2}(α₂, TR). The processing device 120 may also determine S′_{d1} based on Equation (10) below:

$${S}_{d 1}^{′} = \frac{\overline{S ( {α}_{1} , TR )}}{{S}_{d 2} ( {α}_{2} , TR )} . \qquad ( 10 )$$

S′_{d2}-S′_{d8} may be determined based on an approach similar to Equation (9) or Equation (10).

In some embodiments, the number (count) of first MR data sets corresponding to α₁ may be one or more. In some embodiments, the first MR data sets after the first MR data set(s) corresponding to α₁ may also be acquired based on two or more values of flip angle.

It should be noted that the above description is merely provided for the purposes of illustration, and not intended to limit the scope of the present disclosure. For persons having ordinary skills in the art, multiple variations and modifications may be made under the teachings of the present disclosure. However, those variations and modifications do not depart from the scope of the present disclosure.

As shown in FIG. 8B, the processing device 120 may obtain a plurality of first MR data sets Sₑ₁-Sₑ₉. Sₑ₁-Sₑ₉ may be acquired in chronological order. Sₑ₁-Sₑ₉ may be acquired based on two different values of TR (TR₁ and TR₂) and the same flip angle α. Each of Sₑ₁-Sₑ₉ may correspond to the same flip angle a and one of TR₁ and TR₂. Sₑ₁ corresponding to TR₁ may be acquired before Sₑ₂-Sₑ₉ corresponding to TR₂.

As shown in FIG. 8B, the processing device 120 may determine a division of Sₑ₁ and Sₑ₂ to determine a second MR data set S′ₑ₁. S′ₑ₁ may correspond to a time point tₑ₁ within a time period in which Sₑ₂ is acquired. The processing device 120 may determine a division of Sₑ₁ and Sₑ₂ to determine a second MR data set S′ₑ₂. S′ₑ₂ may correspond to a time point tₑ₂ within a time period in which Sₑ₃ is acquired. The processing device 120 may determine a division of Sₑ₁ and Sₑ₄ to determine a second MR data set S′ₑ₃. S′ₑ₃ may correspond to a time point tₑ₃ within a time period in which Sₑ₄ is acquired. The processing device 120 may determine a division of Sₑ₁ and Sₑ₅ to determine a second MR data set S′ₑ₄. S′ₑ₄ may correspond to a time point tₑ₄ within a time period in which Sₑ_{₅} is acquired. The processing device 120 may determine a division of Sₑ₁ and Sₑ₆ to determine a second MR data set S′ₑ₅. S′ₑ₅ may correspond to a time point tₑ₅ within a time period in which Sₑ₆ is acquired. The processing device 120 may determine a division of Sₑ₁ and Sₑ₇ to determine a second MR data set S′ₑ₆. S′ₑ₆ may correspond to a time point tₑ₆ within a time period in which Sₑ₇ is acquired. The processing device 120 may determine a division of Sₑ₁ and Sₑ₈ to determine a second MR data set S′ₑ₇. S′ₑ₇ may correspond to a time point tₑ₇ within a time period in which Sₑ₈ is acquired. The processing device 120 may determine a division of Sₑ₁ and Sₑ₉ to determine a second MR data set S′ₑ₈. S′ₑ₈ may correspond to a time point tₑ₈ within a time period in which Sₑ₉ is acquired.

Taking the second MR data set S′ₑ₁ as an example, the processing device 120 may determine S′ₑ₁ based on Equation (11) below:

$${S}_{e 1}^{′} = \frac{{S}_{e 2} ( α , {TR}_{2} )}{\overline{S ( α , {TR}_{1} )}} , \qquad ( 11 )$$

wherein S̅(̅α̅,̅ T̅R̅₁̅)̅ refers to an average of the first MR data sets corresponding to TR₁. If there is only one first MR data set corresponding to TR₁ (Sₑ₁ shown in FIG. 8B), S̅(̅α̅,̅ T̅R̅₁̅)̅=Sₑ₁(α, TR₁). If there is two or more first MR data sets corresponding to TR₁, e.g., represented as Sₑ₁₁(α, TR₁), Sₑ₁₂(α, TR₁), . . . , Sₑ₁ₙ(α, TR₁), S̅(̅α̅,̅ T̅R̅₁̅)̅=[Sₑ₁₁(α, TR₁)+Sₑ₁₂(α, TR₁)+ . . . +Sₑ₁ₙ(α, TR₁)]/n (n is an integer that is greater than 1).

In some embodiments, to determine the second MR data set S′ₑ₁, there is no limit of the order of the division of S̅(̅α̅,̅ T̅R̅₁̅)̅ and Sₑ₂(α, TR₂). The processing device 120 may also determine S′ₑ₁ based on Equation (12) below:

$${S}_{e 1}^{′} = \frac{\overline{S ( α , {TR}_{1} )}}{{S}_{e 2} ( α , {TR}_{2} )} . \qquad ( 12 )$$

S′ₑ₂-S′ₑ₈ may be determined based on an approach similar to Equation (11) or Equation (12).

In some embodiments, the number (count) of first MR data sets corresponding to TR₁ may be one or more. In some embodiments, the first MR data sets after the first MR data set(s) corresponding to TR₁ may also be acquired based on two or more values of TR.

It should be noted that the above description is merely provided for the purposes of illustration, and not intended to limit the scope of the present disclosure. For persons having ordinary skills in the art, multiple variations and modifications may be made under the teachings of the present disclosure. However, those variations and modifications do not depart from the scope of the present disclosure.

As shown in FIG. 8C, the processing device 120 may obtain a plurality of first MR data sets S_{f1}-S_{f9}. S_{f1}-S_{f9} may be acquired in chronological order. S_{f1}-S_{f9} may be acquired based on two different values of TR (TR₁ and TR₂) and two different values of flip angle (α₁ and α₂). Each of S_{f1}-S_{f9} may correspond to one of α₁ and α₂ and one of TR₁ and TR₂. For example, as shown in FIG. 8C, to acquire S_{f1}-S_{f9}, S_{f1} corresponding to TR₁ and α₁ may be acquired before S_{f2}-S_{f9} corresponding to TR₂ and α₂. As another example, to acquire S_{f1}-S_{f9}, S_{f1} corresponding to TR₂ and α₂ may be acquired before S_{f2}-S_{f9} corresponding to TR₁ and α₁. As still another example, to acquire S_{f1}-S_{f9}, S_{f1} corresponding to TR₁ and α₂ may be acquired before S_{f2}-S_{f9} corresponding to TR₂ and α₁. As further another example, to acquire S_{f1}-S_{f9}, S_{f1} corresponding to TR₂ and α₁ may be acquired before S_{f2}-S_{f9} corresponding to TR₁ and α₂.

As shown in FIG. 8C, the processing device 120 may determine a division of S_{f1} and S_{f2} to determine a second MR data set S′_{f1}. S′_{f1} may correspond to a time point t_{f1} within a time period in which S_{f2} is acquired. The processing device 120 may determine a division of S_{f1} and S_{f2} to determine a second MR data set S′_{f2}. S′_{f2} may correspond to a time point t_{f2} within a time period in which S_{f3} is acquired. The processing device 120 may determine a division of S_{f1} and S_{f4} to determine a second MR data set S′_{f3}. S′_{f3} may correspond to a time point t_{f3} within a time period in which S_{f4} is acquired. The processing device 120 may determine a division of S_{f1} and S_{f5} to determine a second MR data set S′_{f4}. S′_{f4} may correspond to a time point t_{f4} within a time period in which S_{f5} is acquired. The processing device 120 may determine a division of S_{f1} and S_{f6} to determine a second MR data set S′_{f5}. S′_{f5} may correspond to a time point t_{f5} within a time period in which S_{f6} is acquired. The processing device 120 may determine a division of S_{f1} and S_{f7} to determine a second MR data set S′_{f6}. S′_{f6} may correspond to a time point t_{f6} within a time period in which S_{f7} is acquired. The processing device 120 may determine a division of S_{f1} and S_{f8} to determine a second MR data set S′_{f7}. S′_{f7} may correspond to a time point t_{f7} within a time period in which S_{f8} is acquired. The processing device 120 may determine a division of S_{f1} and S_{f9} to determine a second MR data set S′_{f8}. S′_{f8} may correspond to a time point t_{f8} within a time period in which S_{f9} is acquired.

Taking the second MR data set S′_{f1} as an example, the processing device 120 may determine S′_{f1} based on Equation (13) below:

$${S}_{f 1}^{′} = \frac{{S}_{f 2} ( {α}_{2} , {TR}_{2} )}{\overline{S ( {α}_{1} , {TR}_{1} )}} , \qquad ( 13 )$$

wherein S̅(̅α̅₁̅,̅ T̅R̅₁̅)̅ refers to an average of the first MR data sets corresponding to TR₁ and α₁. If there is only one first MR data set corresponding to TR₁ and α₁ (S_{f1} shown in FIG. 8C), S̅(̅α̅₁̅,̅ T̅R̅₁̅)̅=S_{f1}(α₁, TR₁). If there is two or more first MR data sets corresponding to TR₁ and α₁, e.g., represented as S_{f11}(α₁, TR₁), S_{f12}(α₁, TR₁), . . . , S_{f1n}(α₁, TR₁), S̅(̅α̅₁̅,̅T̅R̅₁̅)̅=[S_{f11}(α₁,TR₁)+S_{f12}(α₁,TR₁)+ . . . +S_{f1n}(α₁, TR₁)]/n (n is an integer that is greater than 1).

In some embodiments, to determine the second MR data set S′_{f1}, there is no limit of the order of the division of S̅(̅α̅₁̅,̅ T̅R̅₁̅)̅ and S_{f2}(α₂, TR₂). The processing device 120 may also determine S′_{f1} based on Equation (14) below:

$${S}_{f 1}^{′} = \frac{\overline{S ( {α}_{1} , {TR}_{1} )}}{{S}_{f 2} ( {α}_{2} , {TR}_{2} )} . \qquad ( 14 )$$

S′_{f2}-S′_{f8} may be determined based on an approach similar to Equation (13) or Equation (14).

In some embodiments, the number (count) of first MR data sets corresponding to α₁ and TR₁ may be one or more. In some embodiments, the first MR data sets after the first MR data set(s) corresponding to α₁ and TR₁ may also be acquired based on two or more values of flip angle and two or more values of TR.

It should be noted that the above description is merely provided for the purposes of illustration, and not intended to limit the scope of the present disclosure. For persons having ordinary skills in the art, multiple variations and modifications may be made under the teachings of the present disclosure. However, those variations and modifications do not depart from the scope of the present disclosure.

In some embodiments, as shown in FIGS. 7A-8C, when the plurality of first MR data sets are acquired based on an injection of a contrast agent into the ROI, at least one of the plurality of first MR data sets (e.g., Sₐ₁-Sₐ₃ in FIG. 7A, S_{b1}-S_{b3} in FIG. 7B, S_{c1}-S_{c3} in FIG. 7C, S_{d1}-S_{d3} in FIG. 8A, Sₑ₁-Sₑ₃ in FIG. 8B, S_{f1}-S_{f3} in FIG. 8C) may be acquired before the injection of the contrast agent into the ROI, and the rest of the plurality of first MR data sets (e.g., Sₐ₄-Sₐ₉ in FIG. 7A, S_{b4}-S_{b9} in FIG. 7B, S_{c4}-S_{c9} in FIG. 7C, S_{d4}-S_{d9} in FIG. 8A, Sₑ₄-Sₑ₉ in FIG. 8B, S_{f4}-S_{f9} in FIG. 8C) may be acquired after the injection of the contrast agent.

In some embodiments, as shown in FIGS. 8A-8C, at least one of the plurality of first MR data sets corresponding to a first value of the two or more value of the scan parameter may be collected before the rest of the plurality of first MR data sets corresponding to the rest of the two or more values of the scan parameter. A first portion (e.g., S_{d2}-S_{d3} in FIG. 8A, Sₑ₂-Sₑ₃ in FIG. 8B, S_{f2}-S_{f3} in FIG. 8C) of the rest of the plurality of first MR data sets may be acquired before the injection of the contrast agent into the ROI, and a second portion (e.g., Sₐ₄-Sₐ₉ in FIG. 7A, S_{b4}-S_{b9} in FIG. 7B, S_{c4}-S_{c9} in FIG. 7C, S_{d4}-S_{d9} in FIG. 8A, Sₑ₄-Sₑ₉ in FIG. 8B, S_{f4}-S_{f9} in FIG. 8C) of the rest of the plurality of first MR data sets may be acquired after the injection of the contrast agent.

In some embodiments, the processing device 120 may determine the plurality of second MR data sets using a multi-dimensional integration (MDI) strategy. For example, the processing device 120 may construct an L²-norm minimization problem based on Equation (15) below to determine a second MR data set S′:

$${min}_{{S}^{′}} {\sum }_{1}^{{N}_{c}} {‖ {S}_{i} - {S}_{i} \cdot {S}^{′} ‖}_{2}^{2} , \qquad ( 15 )$$

wherein Nₑ refers to the number (count) of channels for receiving echo signals; and Sᵢ refers to one or more first MR data sets related to the second MR data set S′. For example, if the second MR data set S′ refers to S′ₐ₁ defined based on Equation (3) or Equation (4), Sᵢ refers to Sₐ₁(α₁, TR) or Sₐ₂(α₂, TR). As another example, if the second MR data set S′ refers to S′_{b1} defined based on Equation (5) or Equation (6), Sᵢ refers to S_{b2}(α, TR₂) or S_{b1}(α, TR₁). As still another example, if the second MR data set S′ refers to S′_{c1} defined based on Equation (7) or Equation (8), Sᵢ refers to S_{c2}(α₂, TR₂) or S_{c1}(α₁, TR₁). As further another example, if the second MR data set S′ refers to S′_{d1} defined based on Equation (9) or Equation (10), Sᵢ refers to S_{d2}(α₂, TR) or S̅(̅α̅₁̅,̅ T̅R̅)̅. As yet another example, if the second MR data set S′ refers to S′ₑ₁ defined based on Equation (11) or Equation (12), Sᵢ refers to Sₑ₂(α, TR₂) or S̅(̅α̅,̅ T̅R̅₁̅)̅. As yet another example, if the second MR data set S′ refers to S′_{f1} defined based on Equation (13) or Equation (14), Sᵢ refers to S_{f2}(α₂,TR₂) or S̅(̅α̅₁̅,̅ T̅R̅₁̅)̅.

The processing device 120 may determine the second MR data set S′ by solving Equation (15) using, e.g., least-square optimization.

Details regarding MDI strategy may be found in the reference “Ye Y, Lyu J, Sun W, et al. A multi-dimensional integration (MDI) strategy for MR T2*mapping. NMR Biomed 2021; 34(7):e4529” and/or the reference “Ye Y, Lyu J, Hu Y, Zhang Z, Xu J, Zhang W. Augmented T1 weighted (aT1 W) contrast using dual flip angles acquisition. Proceedings 29th Scientific Meeting, International Society for Magnetic Resonance in Medicine; 2021. p. 2606,” each of which is incorporated herein by reference.

In some embodiments, the processing device 120 may determine the plurality of second MR data sets using other algorithm.

In the plurality of first MR data sets, besides T1 information, there are also non-T1 factors, which may introduce errors and biases to signal analysis, e.g., image reconstruction, physiological analysis, etc. The one or more non-T1 factors may depend on the configuration of the MRI device 110 and tissue properties of the ROI. For example, the one or more non-T1 factors may include T2*, a receiving coil sensitivity, an echo time (TE), a proton density of the ROI, or the like, or any combination thereof.

As illustrated in FIGS. 7A-8C, by determining a second MR data set based on at least two of the plurality of first MR data sets, the one or more non-T1 factors (e.g., M₀ in Equation (2)) in the at least two of the plurality of first MR data sets may be offset, so that the one or more non-T1 factors have less effect on the plurality of second MR data sets than the plurality of first MR data sets, thereby resulting a stronger contrast in the T1 weighted images, and making the subsequent physiological analysis more accurate. In addition, due to the interference of non-T1 factors is eliminated or alleviated in the plurality of second MR data sets, the plurality of second MR data sets may be more sensitive to the T1 shortening effect caused by the contrast agent. So low-dose contrast agent can be used to reduce the cost and the potential impact of the contrast agent on the human body.

It should be noted that the above description is merely provided for the purposes of illustration, and not intended to limit the scope of the present disclosure. For persons having ordinary skills in the art, multiple variations and modifications may be made under the teachings of the present disclosure. However, those variations and modifications do not depart from the scope of the present disclosure. In some embodiments, the Equations provided above are illustrative examples and can be modified in various ways. For example, one or more coefficients in an Equation may be omitted, and/or the Equation may further include one or more additional coefficients.

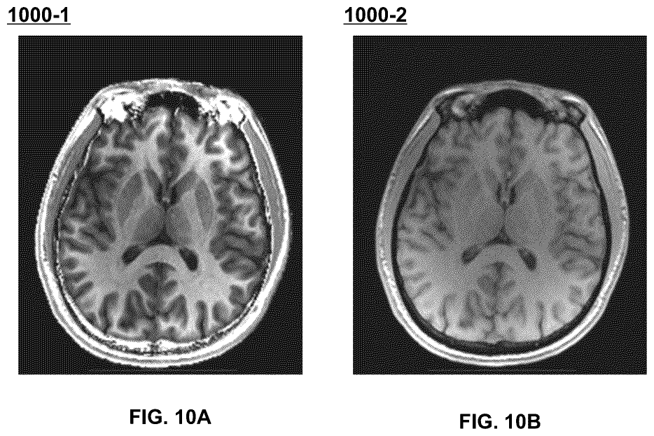

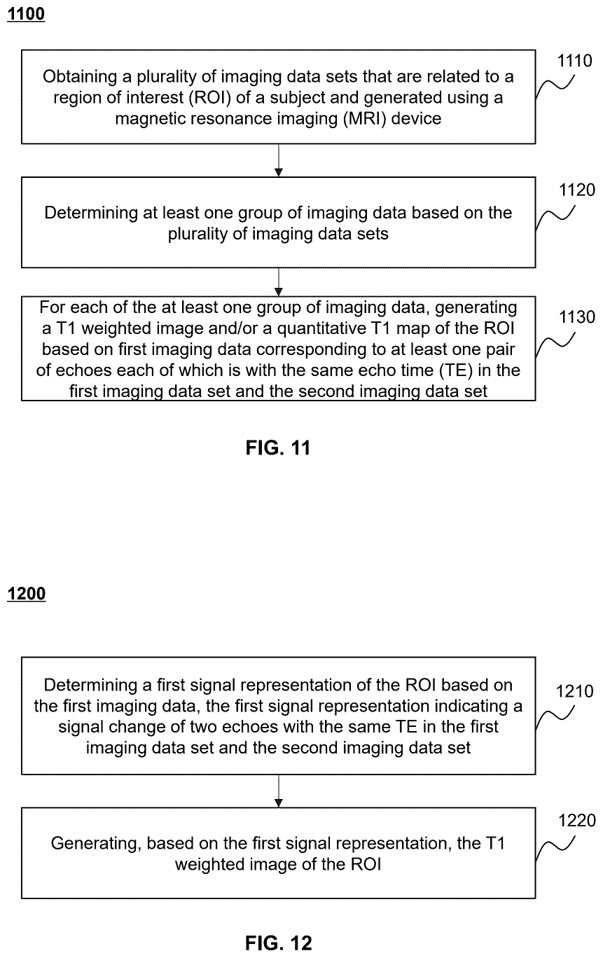

FIG. 10A is a schematic diagram illustrating an exemplary T1 weighted image 1000-1 generated based on a second MR data set (e.g., S′ₐ₁ in FIG. 7A) according to some embodiments of the present disclosure. FIG. 10B is a schematic diagram illustrating an exemplary T1 weighted image 1000-2 generated based on a first MR data set (e.g., Sₐ₁ or Sₐ₂ in FIG. 7A). As shown in FIG. 7A and FIG. 7B, the T1 weighted image 1000-1 has a stronger contrast than the T1 weighted image 1000-2.

It should be noted that the above description is merely provided for the purposes of illustration, and not intended to limit the scope of the present disclosure. For persons having ordinary skills in the art, multiple variations and modifications may be made under the teachings of the present disclosure. However, those variations and modifications do not depart from the scope of the present disclosure.

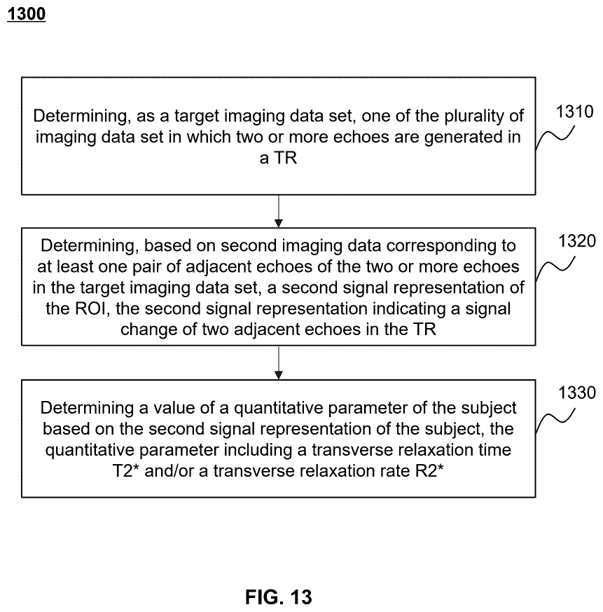

FIG. 11 is a flowchart illustrating an exemplary process 1100 for MRI according to some embodiments of the present disclosure. In some embodiments, the process 1100 may be implemented in the MRI system 100 illustrated in FIG. 1. For example, the process 1100 may be stored in the storage device 130 and/or the storage (e.g., the storage 320, the storage 490) as a form of instructions, and invoked and/or executed by the processing device 120 (e.g., the processor 310 of the computing device 300 as illustrated in FIG. 3, the CPU 440 of the mobile device 400 as illustrated in FIG. 4, or one or more modules illustrated in FIG. 5). The operations of the illustrated process presented below are intended to be illustrative. In some embodiments, the process 1100 may be accomplished with one or more additional operations not described, and/or without one or more of the operations discussed. Additionally, the order in which the operations of the process 1100 as illustrated in FIG. 11 and described below is not intended to be limiting.

In 1110, the processing device 120 may obtain a plurality of imaging data sets that are related to a region of interest (ROI) of a subject and generated using a magnetic resonance imaging (MRI) device (e.g., the MRI device 110). The imaging data set may be similar to the first MR data set illustrated in FIG. 6-FIG. 8C.

In 1120, the processing device 120 may determine at least one group of imaging data based on the plurality of imaging data sets, wherein each of the at least one group of imaging data includes a first imaging data set and a second imaging data set corresponding to two of the two or more different values of the scan parameter, and for at least one of the first imaging data set or the second imaging data set, two or more echoes are generated in a repetition time (TR).

In some embodiments, as described in FIGS. 7A-7C, any two adjacent imaging data sets of the plurality of imaging data sets correspond to two of the two or more different values of the scan parameter. The first imaging data set and the second imaging data set are two adjacent imaging data sets of the plurality of imaging data sets.

For example, as shown in FIG. 7A, the first MR data sets Sₐ₁ and Sₐ₂ are the first imaging data set and the second imaging data set of a first group of imaging data, the first MR data sets Sₐ₂ and Sₐ₃ are the first imaging data set and the second imaging data set of a second group of imaging data, and so on. The first imaging data set and the second imaging data set correspond to different values (α₁ and α₂) of the flip angle and the same TR.

As another example, as shown in FIG. 7B, the first MR data sets S_{b1} and S_{b2} are the first imaging data set and the second imaging data set of a first group of imaging data, the first MR data sets S_{b2} and S_{b3} are the first imaging data set and the second imaging data set of a second group of imaging data, and so on. The first imaging data set and the second imaging data set correspond to different values (TR₁ and TR₂) of TR and the same flip angle.

As still another example, as shown in FIG. 7C, the first MR data sets S_{c1} and S_{c2} are the first imaging data set and the second imaging data set of a first group of imaging data, the first MR data sets S_{c2} and S_{c3} are the first imaging data set and the second imaging data set of a second group of imaging data, and so on. The first imaging data set and the second imaging data set correspond to different values (TR₁ and TR₂) of TR and different values (α₁ and α₂) of the flip angle.

In some embodiments, as described in FIGS. 8A-8C, at least one of the plurality of imaging data sets corresponding to a first value of the two or more different values of the scan parameter is collected before the rest of the plurality of imaging data sets corresponding to the rest of the two or more different values of the scan parameter. When there is only one imaging data set corresponding to the first value of the scan parameter, the imaging data set corresponding to the first value of the scan parameter is determined as the first imaging data set. When there are two or more imaging data sets corresponding to the first value of the scan parameter, an average of the two or more imaging data sets corresponding to the first value of the scan parameter is determined as the first imaging data set. The second imaging data set is one of the rest of the plurality of imaging data sets corresponding to the rest of the two or more different values of the scan parameter.

For example, as shown in FIG. 8A, the first MR data sets S_{d1} and S_{d2} are the first imaging data set and the second imaging data set of a first group of imaging data, the first MR data sets S_{d1} and S_{d3} are the first imaging data set and the second imaging data set of a second group of imaging data, and so on. The first imaging data set corresponds to a flip angle of α₁, the second imaging data set corresponds to a flip angle of α₂ different from α₁, and the first imaging data set and the second imaging data set correspond to the same TR.

As another example, as shown in FIG. 8B, the first MR data sets Sₑ₁ and Sₑ₂ are the first imaging data set and the second imaging data set of a first group of imaging data, the first MR data sets Sₑ₁ and Sₑ₃ are the first imaging data set and the second imaging data set of a second group of imaging data, and so on. The first imaging data set corresponds to TR₁, the second imaging data set corresponds to a TR₂ different from TR₁, and the first imaging data set and the second imaging data set correspond to the same flip angle.

As yet another example, as shown in FIG. 8C, the first MR data sets S_{f1} and S_{f2} are the first imaging data set and the second imaging data set of a first group of imaging data, the first MR data sets S_{f1} and S_{f3} are the first imaging data set and the second imaging data set of a second group of imaging data, and so on. The first imaging data set corresponds to a flip angle of α₁ and TR₁, the second imaging data set corresponds to a flip angle of α₂ different from α₁ and TR₂ different from TR₁.

In 1130, for each of the at least one group of imaging data, the processing device 120 may generate a T1 weighted image and/or a quantitative T1 map of the ROI based on first imaging data corresponding to at least one pair of echoes each of which is with the same echo time (TE) in the first imaging data set and the second imaging data set.

For example, for the first imaging data set, one echo (e_{1,1}) with TE1 is generated in a TR, and for the second imaging data set, two echoes (e_{2,1}, e_{2,2}) with TE1 and TE2 respectively are generated in a TR. The processing device 120 may generate a T1 weighted image and/or a quantitative T1 map of the ROI based on first imaging data corresponding to a pair of echoes (e_{1,1}, e_{2,1}) with the same TE (TE1), and the imaging data corresponding to e_{2,2} in the second imaging data set is not involved in the generation of the T1 weighted image and/or the quantitative T1 map of the ROI.

As another example, for the first imaging data set, two echoes (e_{1,1}, e_{1,2}) with TE1 and TE2 respectively are generated in a TR, and for the second imaging data set, two echoes (e_{2,1}, e_{2,2}) with TE1 and TE2 respectively are generated in a TR. The processing device 120 may generate a T1 weighted image and/or a quantitative T1 map of the ROI based on first imaging data corresponding to a first pair of echoes (e_{1,1}, e_{2,1}) with the same TE (TE1) and a second pair of echoes (e_{1,2}, e_{2,2}) with the same TE (TE2).

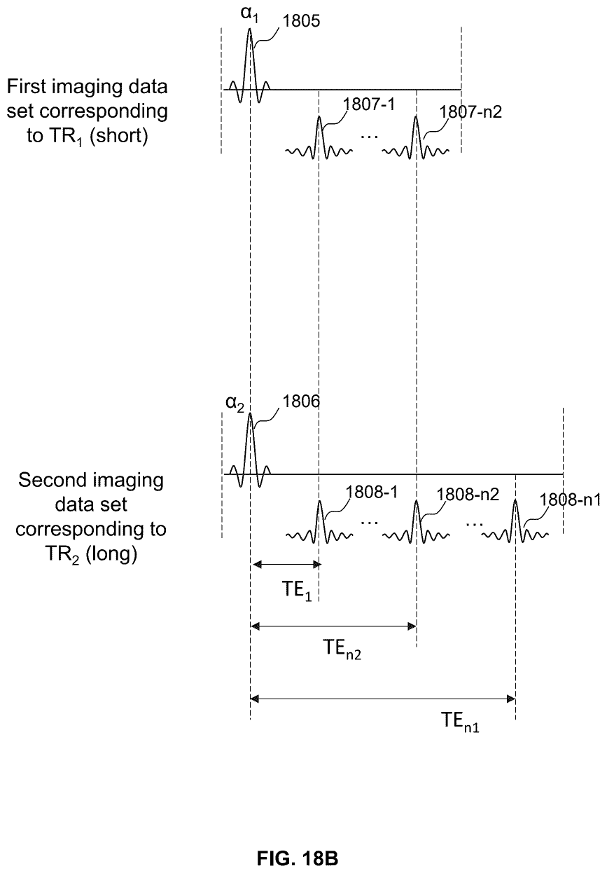

FIGS. 17A-17D are schematic diagrams illustrating exemplary acquisition of a plurality of imaging data sets according to some embodiments of the present disclosure.

The acquisition of a plurality of imaging data sets in FIG. 17A may be similar to FIG. 7B. The time points t₁-t₇ in FIG. 17A may be similar to t_{b1}-t_{b8} in FIG. 7B. The acquisition of a plurality of imaging data sets in FIG. 17B may be similar to FIG. 7C. The time points t₁-t₇ in FIG. 17B may be similar to t_{c1}-t_{c8} in FIG. 7C. The acquisition of a plurality of imaging data sets in FIG. 17C may be similar to FIG. 8B. The time points t₁-t₇ in FIG. 17C may be similar to tₑ₁-tₑ₈ in FIG. 8B. The acquisition of a plurality of imaging data sets in FIG. 17D may be similar to FIG. 8C. The time points t₁-t₇ in FIG. 17D may be similar to t_{f1}-t_{f8} in FIG. 8C.

As shown in FIGS. 17A-17D, the plurality of imaging data sets are acquired using TR₁ and TR₂ (e.g., TR₁ is shorter than TR₂). As shown in FIGS. 17A-17D, the imaging data set corresponding to TR₁ has a shorter acquisition time than the imaging data set corresponding to TR₂.

In some embodiments, if the plurality of imaging data sets are acquired using the same TR, the acquisition time of the plurality of imaging data sets may be the same (as shown in FIG. 7A and FIG. 8A).

In some embodiments, for at least one of the first imaging data set or the second imaging data set, two or more echoes are generated in a TR. In the first imaging data set and the second imaging data set, the count of echoes in a TR may be the same or different.

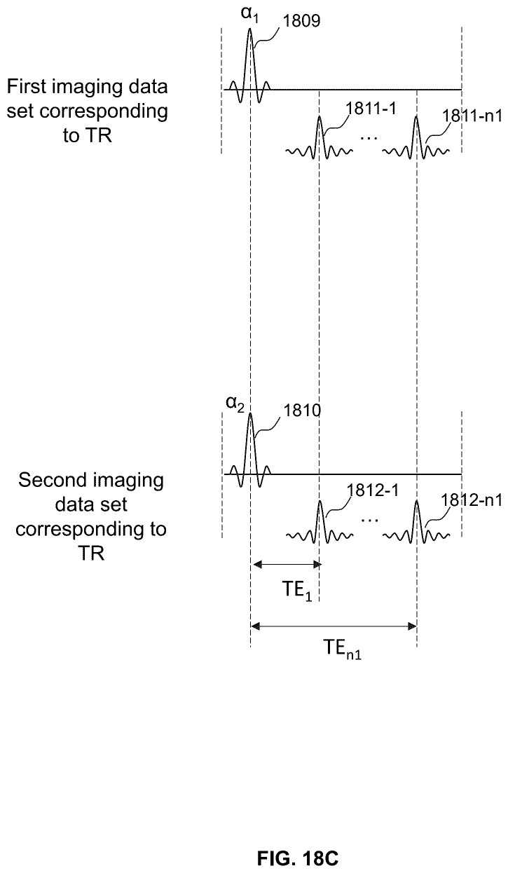

FIGS. 18A-18C are schematic diagrams illustrating exemplary echoes in a TR according to some embodiments of the present disclosure.

In some embodiments, assuming that TR₁ is shorter than TR₂, the count of echoes in TR₁ may be less than the count echoes in TR₂.

For example, as shown in FIG. 18A, in a group of imaging data, the first imaging data set is acquired using a first pulse sequence. The first pulse sequence is with TR₁ and an excitation pulse 1801 with a flip angle of α₁, and in a TR, one echo (echo 1802) with TE₁ is generated. The second imaging data set is acquired using a second pulse sequence. The second pulse sequence is with TR₂ and an excitation pulse 1803 with a flip angle of α₂ (α₁=α₂, or α₁≠α₂), and in a TR, n1 echoes (echoes 1804-1 to 1804-n1) with TE₁-TEₙ₁ is generated, n1 is an integer greater than 1. In this case, echo 1802 in the first imaging data set and echo 1804-1 in the second imaging data set refer to a pair of echoes with the same TE.

As another example, as shown in FIG. 18B, in a group of imaging data, the first imaging data set is acquired using a third pulse sequence. The third pulse sequence is with TR₁ and an excitation pulse 1805 with a flip angle of α₁, and in a TR, n2 echoes (echoes 1807-1 to echoes 1807-n2) with TE₁-TEₙ₂ is generated, n2 is an integer greater than 1. The second imaging data set is acquired using a fourth pulse sequence. The fourth pulse sequence is with TR₂ and an excitation pulse 1806 with a flip angle of α₂ (α₁=α₂, or α₁≠α₂), and in a TR, n1 echoes (echoes 1808-1 to 1808-n1) with TE₁-TEₙ₁ is generated, n1 is an integer greater than 1 and greater than n2. In this case, echo 1807-1 in the first imaging data set and echo 1808-1 in the second imaging data set refer to a pair of echoes with the same TE (TE₁), . . . , echo 1807-n2 in the first imaging data set and echo 1808-n2 in the second imaging data set refer to a pair of echoes with the same TE (TEₙ₂).

As shown in FIG. 18C, in a group of imaging data, the first imaging data set is acquired using a fifth pulse sequence. The fifth pulse sequence is with TR and an excitation pulse 1809 with a flip angle of α₁, and in a TR, n1 echoes (echoes 1811-1 to echoes 1811-n1) with TE₁-TEₙ₁ is generated. The second imaging data set is acquired using a sixth pulse sequence. The sixth pulse sequence is with the same TR and an excitation pulse 1810 with a flip angle of α₂ (α₁=α₂, or α₁≠α₂), and in a TR, n1 echoes (echoes 1812-1 to 1812-n1) with TE₁-TEₙ₁ is generated. In this case, echo 1811-1 in the first imaging data set and echo 1812-1 in the second imaging data set refer to a pair of echoes with the same TE (TE₁), . . . , echo 1811-n1 in the first imaging data set and echo 1812-n1 in the second imaging data set refer to a pair of echoes with the same TE (TEₙ₁).

For the purpose of illustration, one time period of TR is shown in FIGS. 18A-18C. It should be noted that an imaging data set may also include more than one excitation, thereby corresponding to more than one TR.

In some embodiments, when the processing device 120 obtains one group of imaging data, one T1 weighted image and/or one quantitative T1 map of the ROI is generated, achieving static T1 weighted imaging and/or T1 mapping of the ROI. When the processing device 120 obtains two or more groups of imaging data, for each of the two or more groups of imaging data, a T1 weighted image and/or a quantitative T1 map of the ROI is generated, resulting in two or more T1 weighted images and/or quantitative T1 maps of the ROI, so as to achieving dynamic T1 weighted imaging and/or T1 mapping of the ROI. A time point corresponding to each T1 weighted image and/or quantitative T1 map can be found in the description in connection with FIG. 6-FIG. 8C.

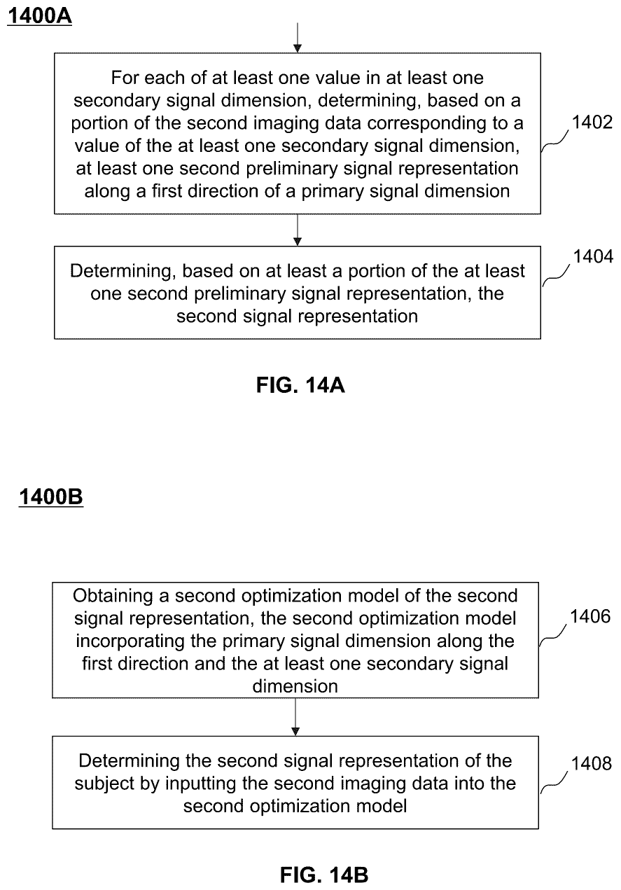

In some embodiments, the processing device 120 may generate a T1 weighted image based on a process 1200 in FIG. 12. The generating a T1 weighted image of the ROI based on signals related to at least one pair of echoes includes: determining a first signal representation of the ROI based on the signals related to the at least one pair of echoes, the first signal representation indicating a signal change of two echoes with the same TE in the first imaging data set and the second imaging data set; and generating, based on the first signal representation, the T1 weighted image of the ROI.

In some embodiments, after the first signal representation is determined, the processing device 120 may determine a T1 value for each voxel of the ROI according to Equation (19) illustrated in FIG. 12, thereby generating a quantitative T1 map of the ROI.

In some embodiments, Equation (17) and Equation (18) illustrated in FIG. 12 may be rewritten as Equation (16) below:

$$\frac{S ( i , j , α , TR )}{sin ( α )} = \frac{S ( i , j , α , TR )}{tan ( α )} E + {M}_{0} ( 1 - E ) \qquad ( 16 )$$

wherein E=e^{-TR/T1}.

Equation (16) may be regarded as a linear equation Y=mX+b between

$$\frac{S ( i , j , α , TR )}{sin ( α )} and \frac{S ( i , j , α , TR )}{tan ( α )} .$$

For each pair of echoes with the same TE, the processing device 120 may determine the slope (m) and the intercept (b) based on S(i, j, α₁, TR₁) and S(i, j, α₂, TR₂), wherein α₁≠α₂, TR₁=TR₂, T1=−TR/ln(m), M₀=b/(1−m), thereby determining a T1 value for each pixel or voxel. For each pixel or voxel, the processing device 120 may determine an average of T1 values determined based on the at least one pair of echoes with the same TE, thereby achieving T1 mapping, e.g., generating a quantitative T1 map.

Description regrading S(i, j, α₁, TR₁) and S(i, j, α₂, TR₂) can be found in the description in connection with FIG. 12.

FIG. 12 is a flowchart illustrating an exemplary process for generating a T1 weighted image according to some embodiments of the present disclosure. In some embodiments, the process 1200 may be implemented in the MRI system 100 illustrated in FIG. 1. For example, the process 1200 may be stored in the storage device 130 and/or the storage (e.g., the storage 320, the storage 490) as a form of instructions, and invoked and/or executed by the processing device 120 (e.g., the processor 310 of the computing device 300 as illustrated in FIG. 3, the CPU 440 of the mobile device 400 as illustrated in FIG. 4, or one or more modules illustrated in FIG. 5). The operations of the illustrated process presented below are intended to be illustrative. In some embodiments, the process 1200 may be accomplished with one or more additional operations not described, and/or without one or more of the operations discussed. Additionally, the order in which the operations of the process 1200 as illustrated in FIG. 12 and described below is not intended to be limiting.

In 1210, the processing device 120 may determine a first signal representation of the ROI based on the first imaging data corresponding to the at least one pair of echoes, the first signal representation indicating a signal change of two echoes with the same TE in the first imaging data set and the second imaging data set.

Merely by way of example, the first imaging data set corresponds to TR₁ and a flip angle of α₁, and the second imaging data set corresponds to TR₂ and a flip angle of α₂, wherein α₁≠α₂, and TR₁=TR₂; or α₁=α₂, and TR₁≠TR₂; or α₁≠α₂, and TR₁≠TR₂. Imaging data corresponding to an echo refers to a signal corresponds to an echo and a coil channel (a signal determined by detecting the echo using the coil channel). In the first imaging data set, imaging data corresponding to the ith echo and the jth coil channel may be expressed as Equation (17) below:

$$S ( i , j , {α}_{1} , {TR}_{1} ) = {M}_{0} \frac{( 1 - {E}_{1} ) sin ( {α}_{1} )}{1 - {E}_{1} cos ( {α}_{1} )} \qquad ( 17 )$$

wherein S(i, j, α₁, TR₁) refers to the imaging data corresponding to the ith echo and the jth coil channel in the first imaging data set that corresponds to TR₁ and α₁; E₁=e−^{TR}^{₁}^{/T1}; M₀ is the base signal that includes one or more non-T1 factors (e.g., related to equilibrium magnetization) of the ROL. The one or more non-T1 factors may depend on the configuration of the MRI device 110 and tissue properties of the ROI. For example, the one or more non-T1 factors may include T2*, a receiving coil sensitivity, an echo time (TE), a proton density of the ROI, or the like, or any combination thereof. Merely by way of example, M₀=CⱼØe^{-TE}^{ᵢ}^{/T2*}, wherein Cⱼ refers to a coil sensitivity factor of the jth coil channel, TE, refers to TE of the ith echo, and Ø refers to the proton density. In the second imaging data set, imaging data corresponding to the ith echo and the jth coil channel (a signal generated by detecting the ith echo using the jth coil channel) may be expressed as Equation (18) below:

$$S ( i , j , {α}_{2} , {TR}_{2} ) = {M}_{0} \frac{( 1 - {E}_{2} ) sin ( {α}_{2} )}{1 - {E}_{2} cos ( {α}_{2} )} \qquad ( 18 )$$

wherein S(i, j, α₂,TR₂) refers to the imaging data corresponding to the ith echo and the jth coil channel in the second imaging data set that corresponds to TR₂ and α₂, and E₂=e^{-TR}^{₂}^{/T1}. The first imaging data corresponding to a pair of echoes refers to the imaging data corresponding to echoes with the same TE and the same coil channel in the first imaging data set and the second imaging data set, e.g., the first imaging data corresponding to a pair of echoes refers to S(i, j, α₁, TR₁) and S(i, j, α₂, TR₂).

In some embodiments, the first signal representation is defined as a ratio between two echoes with the same TE in the first MR data set and the second MR data set. For example, the first signal representation may be defined as Equation (19) below:

$$Δ S = \frac{S ( i , j , {α}_{1} , {TR}_{1} )}{S ( i , j , {α}_{2} , {TR}_{2} )} = \frac{1 - {E}_{2} cos ( {α}_{2} )}{1 - {E}_{1} cos ( {α}_{1} )} \cdot \frac{( 1 - {E}_{1} ) sin ( {α}_{1} )}{( 1 - {E}_{2} ) sin ( {α}_{2} )} \qquad ( 19 )$$

wherein ΔS refers to the first signal representation. Equation (19) is merely provided for the purposes of illustration, and the first signal representation may also be defined as

$$\frac{S ( i , j , {α}_{2} , T {R}_{2} )}{S ( i , j , {α}_{1} , {TR}_{1} ) .}$$

In some embodiments, the generating a T1 weighted image of the ROI based on first imaging data corresponding to at least one pair of echoes includes: establishing a first optimization model based on the first imaging data and the first signal representation; and determining the first signal representation by minimizing a value of the first optimization model.

The first optimization model may be expressed as Equation (20) below:

$${min}_{Δ S} {\sum }_{1}^{{N}_{c}} {\sum }_{1}^{{N}_{e}} {‖ S ( i , j , {α}_{1} , {TR}_{1} ) - S ( i , j , {α}_{2} , {TR}_{2} ) \cdot Δ S ‖}_{2}^{2} , \qquad ( 20 )$$

wherein N_{c} refers to the number (count) of coil channels for detecting echoes; S(i, j, α₁, TR₁) and S(i, j, α₂, TR₂) refer to the first imaging data corresponding to the same coil channel and a pair of echoes with the same TE; and Nₑ refers to the number (count) of the at least one pair of echoes. The processing device 120 may determine the first signal representation by solving Equation (20) using, e.g., least-square optimization, a neural network model, a support vector machine (SVM), or the like, or any combination thereof.

In some embodiments, the determining a first signal representation of the ROI based on the first imaging data corresponding to the at least one pair of echoes includes: for each of the at least one pair of echoes, determining a first preliminary signal representation of the ROI; and determining the first signal representation based on the first preliminary signal representation of the at least one pair of echoes.

For example, for a pair of the ith echoes corresponding to the jth coil channel in the first imaging data set and the second imaging data set, the processing device 120 may determine a first preliminary signal representation of the ROI by determining a ratio between the signals related to the pair of the ith echoes. The first signal representation may be a sum, an average value, or a median value of the at least first preliminary signal representation of the at least one pair of echoes.

In 1220, the processing device 120 may generate, based on the first signal representation, the T1 weighted image of the ROI. For example, the processing device 120 may perform image reconstruction on the first signal representation to obtain the T1 weighted image of the ROI.

In imaging data corresponding to an echo and a coil channel, besides T1 information, there are also non-T1 factors (e.g., related to equilibrium magnetization), such as T2*, a coil sensitivity factor of a coil channel, an echo time (TE), a proton density of the ROI etc. For T1 weighted imaging and T1 mapping, the non-T1 factors may introduce errors and biases to signal analysis, e.g., image reconstruction, physiological analysis, etc.

By defining the first signal representation by determining a ratio between two echoes with the same TE in the first MR data set and the second MR data set, the one or more non-T1 factors may be offset, so that the one or more non-T1 factors have less effect on the first signal representation than the first imaging data set and the second imaging data set, thereby resulting a stronger contrast in the T1 weighted images, and making the subsequent physiological analysis more accurate. In addition, because the interference of non-T1 factors are eliminated or alleviated in the first signal representation, the first signal representation may be more sensitive to the T1 shortening effect caused by the contrast agent. So low-dose contrast agent can be used to reduce the cost and the potential impact of the contrast agent on the human body.

By introducing a plurality of pairs of echoes into the determination of the first signal representation, the signal-to-noise ratio of the T1 weighted image can be improved.

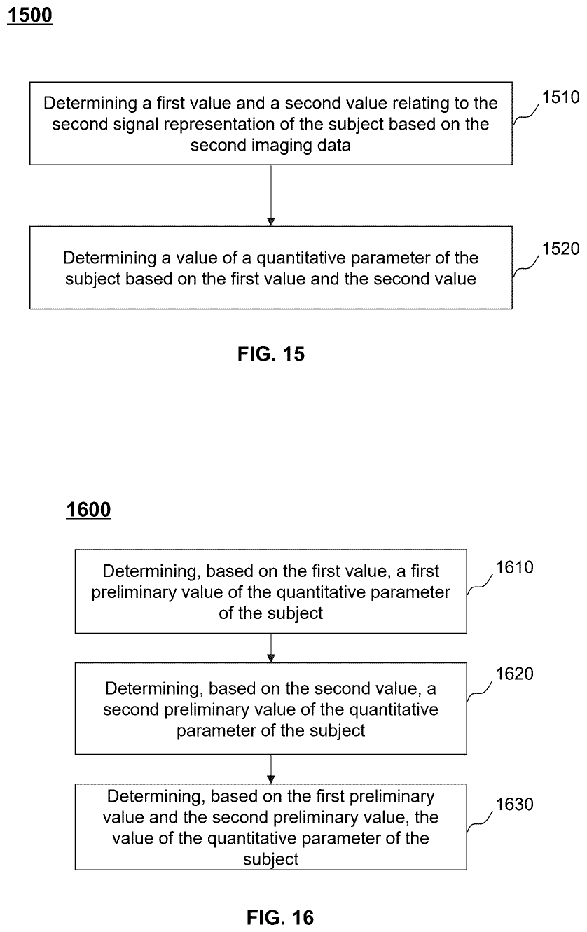

FIG. 13 is a flowchart illustrating an exemplary process for MRI according to some embodiments of the present disclosure. In some embodiments, the process 1300 may be implemented in the MRI system 100 illustrated in FIG. 1. For example, the process 1300 may be stored in the storage device 130 and/or the storage (e.g., the storage 320, the storage 490) as a form of instructions, and invoked and/or executed by the processing device 120 (e.g., the processor 310 of the computing device 300 as illustrated in FIG. 3, the CPU 440 of the mobile device 400 as illustrated in FIG. 4, or one or more modules illustrated in FIG. 5). The operations of the illustrated process presented below are intended to be illustrative. In some embodiments, the process 1300 may be accomplished with one or more additional operations not described, and/or without one or more of the operations discussed. Additionally, the order in which the operations of the process 1300 as illustrated in FIG. 13 and described below is not intended to be limiting.

In some embodiments, the processing device 120 may select, as a target imaging data set, one of the plurality of imaging data set in which two or more echoes are generated in a TR, determine a second signal representation based on the target imaging data set, and determine a value of T2* and/or R2* of the ROI based on the second signal representation. If two or more echoes are generated in a TR in each of the plurality of imaging data sets, the processing device 120 may perform the process 1300 for each of the plurality of imaging data sets to generate a plurality of quantitative T2* maps of the ROI, thereby achieving dynamic T2* mapping.

In 1310, the processing device 120 may determine, as a target imaging data set, one of the plurality of imaging data set in which two or more echoes are generated in a TR.

In 1320, the processing device 120 may determine, based on second imaging data corresponding to at least one pair of adjacent echoes of the two or more echoes in the target imaging data set, a second signal representation of the ROI, the second signal representation indicating a signal change of two adjacent echoes in the TR.

The processing device 120 may determine the second signal representation of the ROI based on the second imaging data corresponding to the at least one pair of adjacent echoes of the two or more echoes in the target imaging data set, a primary signal dimension, and at least one secondary signal dimension. The primary signal dimension is the TE, and the at least one secondary signal dimension is not associated with the second signal representation.

In some embodiments, imaging data related to an echo may correspond to a set of values in a plurality of signal dimensions of signal acquisition using the MRI device. As used herein, a signal dimension of a signal may refer to a parameter that describes an instance under which the signal is determined or acquired using the MRI device. In some embodiments, the plurality of signal dimensions may include an echo time (TE), an unit repetition time (TR), an inversion recovery time (TI), a b-value, a T1 p-preparation duration, a T2-preparation duration, a repetition, a velocity encoding value, a count of radio frequency (RF) channels, a flip angle, an RF center frequency, an RF receiving coil unit, or the like, or any combination thereof.

For example, the MRI device may be caused to apply a multi-echo pulse sequence on the ROI to collect the target imaging data set. In a TR, each of the m coil units (coil channels) may detect n echoes sequentially occurred at different TEs (denoted as TE₁, TE₂, . . . , and TEₙ). In some embodiments, the n echoes may sequentially occur at a substantially same time interval (denoted as ΔTE) between successive echoes. For a physical point Pᵣ of the subject,

$${S}_{{e}_{i}}^{j} ( r )$$

refers to the imaging data corresponding to the i^{th} echo detected by the j^{th} coil unit, i=1, 2, . . . , n, j=1, 2, . . . , m. Exemplary signal dimensions may include an echo time, a coil unit, or the like, or any combination thereof. For example,

$${S}_{{e}_{i}}^{j} ( r )$$

may correspond to TEᵢ in the echo time dimension, and j in the coil unit dimension. It should be noted that the above example is merely provided for the purposes of illustration, and not intended to limit the scope of the present disclosure. For example, the multi-echo pulse sequence applied on the ROI may include more than one repetition and/or more than one flip angle.

The processing device 120 may determine, among the plurality of signal dimensions, a primary signal dimension associated with a second signal representation of the subject.

As used herein, the second signal representation may refer to a representative value or an attribute value of the signals of the subject. The second signal representation of the subject may reflect one or more physiological characteristics or physical characteristics of the subject, which may provide a basis for medical diagnosis and/or treatment.

A signal dimension may be regarded as being associated with the second signal representation if the signal dimension and the second signal representation have a certain mathematical correlation (e.g., an index correlation, a linear correlation, or any other mathematical correlation). For illustration purposes, the Pᵣ is described as an exemplary subject. Referring back to the example above, the MRI device may be caused to scan the ROI using the multi-echo pulse sequence. The second signal representation of Pᵣ may be a change of signal intensity at P, over the time interval ΔTE between successive echoes (between two adjacent echoes in a TR), which is denoted as ΔS1(r). As used herein, a signal intensity at Pᵣ may refer to an intensity or strength of MRI signals of Pr. In some embodiments, the second signal representation ΔS1(r) may be associated with the echo time as illustrated in Equation (21) below:

$$Δ S 1 ( r ) = {e}^{- Δ TE / {T}_{2}^{*} ( r ) + i γ Δ B ( r ) Δ T E} \qquad ( 21 )$$

where

$${T}_{2}^{*} ( r )$$

refers to a transverse relaxation time of Pᵣ, γ refers to a gyromagnetic ratio, ΔB(r) refers to a local field distribution at Pᵣ. In this case, the primary signal dimension may be the echo time that is associated with ΔS1(r).

The at least one secondary signal dimension may include any signal dimension of the signals of the subject other than the primary signal dimension. In some embodiments, each of the at least one secondary signal dimension may be not associated (or correlate) with the second signal representation. In some embodiments, the at least one secondary signal dimension may include all or a portion of the signal dimension(s) of the signals of the subject other than the primary signal dimension. In some embodiments, a signal dimension may be determined as a secondary signal dimension if it is not associated with the second signal representation and has two or more values in the signal dimension. For example, referring back to the example above, the at least one secondary signal dimension may include the dimension of coil unit, which is not associated with the ΔS1(r) according to Equation (21) as described above.

In some embodiments, two or more signal dimensions of the plurality of signal dimensions may be associated with the second signal representation. One of the two or more signal dimensions may be selected as the primary signal dimension. The selection may be performed by the processing device 120 autonomously or based on a user instruction. The unselected signal dimension(s) associated with the signal representation may be designated as one or more secondary signal dimensions or be omitted from processing.

The processing device 120 may determine the second signal representation of the subject based on second imaging data corresponding to at least one pair of adjacent echoes of the two or more echoes in the target imaging data set, the primary signal dimension, and the at least one secondary signal dimension.

The second imaging data corresponding to a pair of adjacent echoes refers to the imaging data corresponding to two adjacent echoes in a TR, e.g., the second imaging data corresponding to a pair of adjacent echoes refers to S(i, j, α, TR) and S(i+1, j, α, TR).

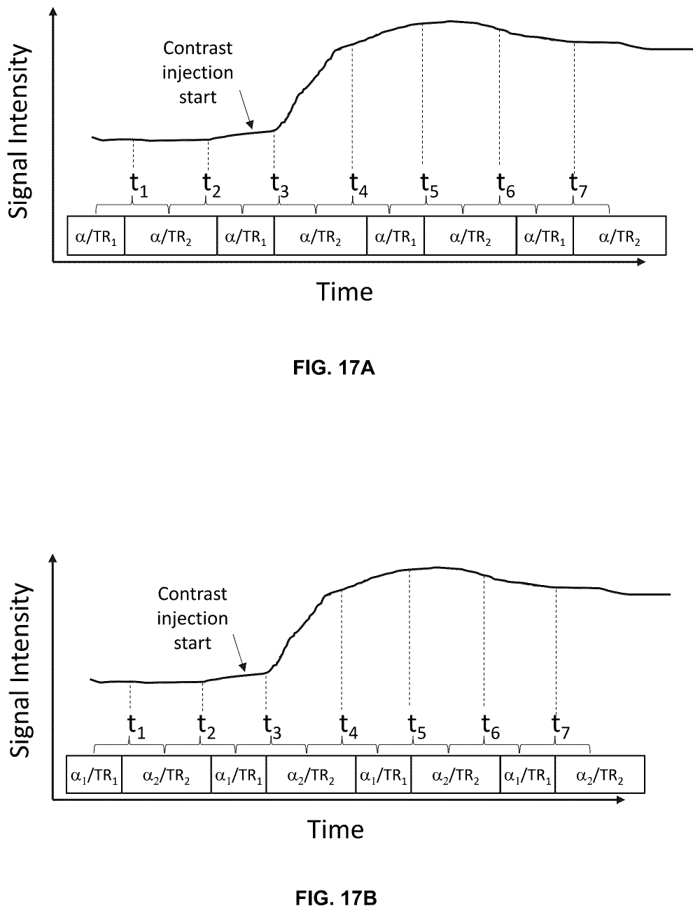

In some embodiments, the processing device 120 may determine the second signal representation of the subject by performing one or more operations in process 1400A as described in connection with FIG. 14A. Alternatively, the processing device 120 may determine the second signal representation of the subject based on a second optimization model of the second signal representation by performing one or more operations in process 1400B as described in connection with FIG. 14B. In some embodiments, the second signal representation of the subject may be represented by a complex number or a real number value. In some embodiments, the second signal representation of the subject may be described in the form of a function, such as Equation (21).

In some embodiments, the subject may be a physical point of a patient as described above. The patient may include one or more other physical points. For each physical point of the patient, operation 1320 may be performed to determine a second signal representation of the physical point. The second signal representations of the physical points of the patient may reflect one or more physiological or physical characteristics of different portions of the patient, and thereby can be used in disease diagnoses. In some embodiments, the processing device 120 may generate an image including a plurality of pixels corresponding to the physical points of the patient, wherein the pixel values of the pixels may be determined based on the second signal representations of the corresponding physical points. The image may intuitively reflect the second signal representations of different physical points of the patient and serve as a basis of disease diagnosis.

The processing device 120 may generate a T2* weighted image by reconstructing the second signal representation.

In some embodiments, the process 1300 may further include an additional operation 1330.

In 1330, the processing device 120 may determine a value of a quantitative parameter of the subject based on the second signal representation of the subject. The quantitative parameter includes a transverse relaxation time T2* and/or a transverse relaxation rate R2* (R2*=1/T2*).

In some embodiments, the second signal representation of the subject may be associated with the quantitative parameter. The primary signal dimension may be associated with the quantitative parameter. Each of the at least one secondary signal dimension may be not associated with the quantitative parameter. In some embodiments, a quantitative parameter may be regarded as being associated with a signal dimension if the quantitative parameter and the signal dimension have a certain correlation, e.g., a correlation that may be presented or described using a mathematical relationship (e.g., an index correlation, a linear correlation, or any other mathematical correlation).

For illustration purposes, the physical point Pᵣ of the patient is described as an exemplary subject and a determination of exemplary quantitative parameters of Pᵣ is provided hereinafter. For example, the second signal representation of Pᵣ may be ΔS1(r) and the quantitative parameter may include

$${T}_{2}^{*} ( r ) and / or {R}_{2}^{*} ( r ) ( {R}_{2}^{*} ( r ) = \frac{1}{{T}_{2}^{*} ( r )} ) ,$$

wherein both

$${T}_{2}^{*} ( r ) and {R}_{2}^{*} ( r )$$

are associated with the echo time (i.e., the primary signal dimension with respect to ΔS1(r)) according to Equation (21).

In some embodiments, the second signal representation of the subject may be a processing result in K-space. The quantitative parameter may be any parameter that is associated with the processing result in K-space. In some embodiments, the quantitative parameter may be data in K-space. Alternatively, the quantitative parameter may be data in the image domain, wherein the determination of the value of the quantitative parameter may be performed in image reconstruction. For instance, by way of determining one or more quantitative parameters in the image domain from signal representation(s) in K-space, image reconstruction is achieved.

In some embodiments, the processing device 120 may obtain a relationship relating to second signal representations of the subject and values of the quantitative parameter. The processing device 120 may further determine the value of the quantitative parameter of the subject based on the second signal representation of the subject and the relationship. For example, the relationship may be described in the form of a correlation function, such as Equation (21). The processing device 120 may determine the value of the quantitative parameter by solving the correlation function. As another example, the relationship may be presented in the form of a table or curve recording different second signal representations and their corresponding values of the quantitative parameter. The processing device 120 may determine the value of the quantitative parameter by looking up the table or consulting the curve.

In some embodiments, the second signal representation determined in operation 1320 may be represented by a complex number including a phase component and an amplitude component. The value of the quantitative parameter may be determined based on at least one of the phase component or the amplitude component of the complex number. Alternatively, the second signal representation may be represented by a real number, and the value of the quantitative parameter may be determined based on the real number. Taking the physical point Pᵣ as an example, the second signal representation may be ΔS1(r) described above. If ΔS1(r) is a real number,

$${T}_{2}^{*} ( r )$$

may be determined based on ΔS1(r). If ΔS1(r) is a complex number,

$${T}_{2}^{*} ( r )$$

may be determined based on the amplitude component of ΔS1(r) according to Equation (22) below:

$${T}_{2}^{*} ( r ) = - Δ TE / ln ( \vert Δ S 1 ( r ) \vert ) , \qquad ( 22 )$$

In some embodiments, the subject may be a physical point of a patient as described above. The patient may include one or more other physical points each of whose signal representation or value of a quantitative parameter is of interest. The processing device 120 may perform operation 1330 for each physical point of the patient to determine a corresponding value of the quantitative parameter. The values of the quantitative parameter of the physical points may reflect one or more physiological or physical characteristics of different portions of the patient, and thereby can be used in disease diagnosis. Optionally, the processing device 120 may generate a quantitative parameter map (e.g., a T2* map, a R2* map) of the patient based on the values of the quantitative parameter of the physical points of the patient. The quantitative parameter map may be used for medical diagnosis.

It should be noted that the above description regarding the process 1300 is merely provided for the purposes of illustration, and not intended to limit the scope of the present disclosure. For persons having ordinary skills in the art, multiple variations and modifications may be made under the teachings of the present disclosure. However, those variations and modifications do not depart from the scope of the present disclosure. In some embodiments, the process 1300 may be accomplished with one or more additional operations not described and/or without one or more of the operations discussed above. For example, operation 1330 may be omitted. In some embodiments, the order in which the operations of the process 1300 described above is not intended to be limiting.

FIGS. 14A and 14B are flowcharts illustrating exemplary processes for determining a second signal representation of a subject according to some embodiments of the present disclosure. In some embodiments, the process 1400A and the process 1400B may be implemented in the MRI system 100 illustrated in FIG. 1. For example, the process 1400A and the process 1400B may be stored in the storage device 130 and/or the storage (e.g., the storage 320, the storage 490) as a form of instructions, and invoked and/or executed by the processing device 120 (e.g., the processor 310 of the computing device 300 as illustrated in FIG. 3, the CPU 440 of the mobile device 400 as illustrated in FIG. 4, or one or more modules illustrated in FIG. 5). The operations of the illustrated process presented below are intended to be illustrative. In some embodiments, the process 1400A and the process 1400B may be accomplished with one or more additional operations not described, and/or without one or more of the operations discussed. Additionally, the order in which the operations of the process 1400A and the process 1400B as illustrated in FIG. 14A and FIG. 14B and described below is not intended to be limiting.

In some embodiments, one or more operations of the process 1400A may be performed to achieve at least part of operation 1320 as described in connection with FIG. 13.

In 1402, for at least one value in the at least one secondary signal dimension, the processing device 120 may determine at least one second preliminary signal representation of the subject associated with the primary signal dimension based on a portion of the second imaging data corresponding to the value of the at least one secondary signal dimension.

For each pair of adjacent echoes in the target imaging data set, the processing device 120 may determine at least one second preliminary signal representation based on the second imaging data related to the pair of adjacent echoes, and determine, based on at least a portion of the at least one second preliminary signal representation of the subject, the second signal representation of the subject.

For illustration purposes, the following description is provided with reference to the example described in connection with FIG. 13. It is assumed that the second signal representation to be determined is ΔS1(r) (i.e., the change of signal intensity at the physical point P, of the patient over ΔTE). As described above, the primary signal dimension associated with ΔS1(r) may be the echo time, and the at least one secondary signal dimension may include the coil unit. In some embodiments, for at least one coil unit (i.e., for at least one value in the dimension of coil unit), the processing device 120 may determine at least one second preliminary signal representation associated with the echo time.

Merely by way of example, for Coil₁, the processing device 120 may determine at least one second preliminary signal representation based on the signals of Pᵣ corresponding to Coil₁, that is,

$${S}_{{e}_{1}}^{1} ( r ) to {S}_{{e}_{n}}^{1} ( r ) .$$

The at least one second preliminary signal representation may include

$$Δ {S}_{2 - 1}^{1} ( r ) , Δ {S}_{3 - 2}^{1} ( r ) , … , and Δ {S}_{n - ( n - 1 )}^{1} ( r ) ,$$

wherein

$$Δ {S}_{i - ( i - 1 )}^{1} ( r )$$

refers to a change of signal intensity with respect to Coil₁ at Pᵣ over a time interval between a pair of adjacent echoes TEᵢ and TEᵢ₋₁.

$$Δ {S}_{i - ( i - 1 )}^{1} ( r )$$

may be determined based on

$${S}_{{e}_{i}}^{1} ( r ) and {S}_{{e}_{i - 1}}^{1} ( r ) .$$

For example,

$$Δ {S}_{i - ( i - 1 )}^{1} ( r )$$

may be equal to

$${S}_{{e}_{i}}^{1} ( r ) / {S}_{{e}_{i - 1}}^{1} ( r ) .$$

Similarly, the processing device 120 may determine at least one second preliminary signal representation for each of the other coil units. In this way, m*(n−1) second preliminary signal representations of Pᵣ may be determined. In some embodiments, the processing device 120 may determine at least one second preliminary signal representation for a portion of the coil units. In this way, fewer than m*(n−1) second preliminary signal representations of Pᵣ may need to be determined.

It should be noted that the above description regarding the example is merely provided for the purposes of illustration, and not intended to limit the scope of the present disclosure. For persons having ordinary skills in the art, multiple variations and modifications may be made under the teachings of the present disclosure. However, those variations and modifications do not depart from the scope of the present disclosure. For example, the processing device 120 may determine one second preliminary signal representation (denoted as

$$Δ {S}_{1}^{1} )$$

### for Coil₁.

$$Δ {S}_{1}^{1}$$

may be equal to an average value of

$$Δ {S}_{2 - 1}^{1} ( r ) , Δ {S}_{3 - 2}^{1} ( r ) , … , and Δ {S}_{n - ( n - 1 )}^{1} ( r ) .$$

Alternatively, the processing device 120 may determine ΔS₁¹ by inputting

$${S}_{{e}_{1}}^{1} ( r ) to {S}_{{e}_{n}}^{1} ( r )$$

into a second optimization model (e.g., Equation (23)) as described elsewhere in this disclosure (e.g., FIG. 14B and the relevant descriptions). In some embodiments, the at least one secondary signal dimension of the signals of the physical point Pᵣ described above is illustrative. The at least one secondary signal dimension of the signals of Pᵣ may include a repetition. Additionally or alternatively, the at least one secondary signal dimension of the signals of Pᵣ may further include one or more other secondary signal dimensions, such as one or more imaging parameters of the MRI device.

In 1404, the processing device 120 (e.g., the determination module 504) may determine the second signal representation of the subject based on at least a portion of the at least one second preliminary signal representation of the subject.

In some embodiments, the second signal representation may be a sum, an average value, or a median value of the at least a portion of the at least one second preliminary signal representation. In some embodiments, all of the at least one second preliminary signal representation determined in operation 1402 may be used to determine the signal representation of the subject. Alternatively, only a portion of the at least one second preliminary signal representation determined in operation 1402 may be used to determine the signal representation of the subject. Taking the example illustrated in FIG. 13 as an instance, the processing device 120 may determine the second signal representation based on the second preliminary signal representations corresponding to Coil₁ to Coilₘ₋₁, for example, if Coilₘ has some operation faults.

In some embodiments, one or more operations of the process 1400B may be performed to achieve at least part of operation 1330 as described in connection with FIG. 13.

In 1406, the processing device 120 may obtain a second optimization model of the second signal representation of the subject, wherein the second optimization model may incorporate the primary signal dimension and the at least one secondary signal dimension.

The processing device 120 may establish a second optimization model based on the second signal representation and the second imaging data, and determine the second signal representation by minimizing a value of the second optimization model.

Taking the example illustrated in FIG. 13 as an example, the second optimization model may be expressed as an Equation (23) as below:

$$arg {min}_{Δ S 1 ( r )} {\sum }_{i}^{{N}_{e c h} - 1} \sum {N}_{c h} {‖ {S}_{{e}_{i + 1}} ( r ) - {S}_{{e}_{i}} ( r ) Δ S 1 ( r ) ‖}_{2}^{2} , \qquad ( 23 )$$

where N_{ech} refers the count of values in the echo time dimension (i.e., n), N_{ch} refers to the count of values in the coil unit (i.e., m), and Sₑ_{ᵢ₊₁}(r) and Sₑ_{ᵢ}(r) refer to the second imaging data corresponding to a pair of successive (adjacent) echoes detected by one coil unit. It should be noted that the Equation (23) illustrated above is merely provided for the purposes of illustration, and not intended to limit the scope of the present disclosure. In some embodiments, the signals of the physical point P, may have one or more other secondary signal dimensions, and the other secondary signal dimension(s) may be incorporated in the Equation (23), for example, in a similar manner as the coil unit.

In 1408, the processing device 120 may determine the second signal representation of the subject by inputting the second imaging data into the second optimization model.

Taking the physical point P, as an example, the processing device 120 may input the signals

$$( i . e . , {S}_{{e}_{1}}^{1} ( r ) to {S}_{{e}_{n}}^{m} ( r ) )$$

into Equation (23) and solve Equation (23) to determine ΔS1(r). In some embodiments, the processing device 120 may solve the second optimization model using a least square method, a neural network model, a support vector machine (SVM), or the like, or any combination thereof.

In some embodiments, for at least one value in the at least one secondary signal dimension, the processing device 120 may determine at least one pair of signals corresponding to the value in the at least one secondary signal dimension. Each pair of the at least one pair of signals may correspond to different values in the primary signal dimension. For example, for Coil₁, the processing device 120 may determine (n−1) pairs of signals corresponding to successive echoes detected by Coilᵢ, such as a first pair of

$${S}_{{e}_{1}}^{1} ( r ) and {S}_{{e}_{2}}^{1} ( r ) ,$$

a second pair of

$${S}_{{e}_{2}}^{1} ( r ) and {S}_{{e}_{3}}^{1} ( r ) ,$$

or the like. The processing device 120 may further determine the second signal representation of the subject by inputting the at least one pair of signals (the second imaging data) into the second optimization model. For example, the at least one pair of signals (the second imaging data) may be inputted into Equation (23) to determine ΔS1(r).

In the processes 1400A and 1400B, the second signal representation of the subject is determined by jointly processing signals of different signal dimensions, including the primary signal dimension and the at least one secondary signal dimension. This may improve the efficiency and/or accuracy of signal representation determination compared with processing signals of different signal dimensions independently. For example, in the process 1400A, one or more second preliminary signal representations may be determined for each coil unit (i.e., for each value in a secondary signal dimension). The second signal representation of the subject may be determined based on the second preliminary signal representations of all coil units of the MRI device. For example, the second signal representation of the subject may be an average of the second preliminary signal representations of all coil units of the MRI device. In addition, in some embodiments, a second preliminary signal representation may be determined based on a comparison between signals detected by different coil units, for example, the second preliminary signal representation for Pᵣ may be equal to

$${S}_{{e}_{i}}^{1} ( r ) / {S}_{{e}_{i - 1}}^{1} ( r )$$

as described above. This may reduce the influence of coil performance (e.g., a sensitivity distribution, a signal-to-noise ratio (SNR)) on the second signal representation, thereby improving the accuracy of the determined second signal representation. As another example, in the process 1400B, a second optimization model, which incorporates and processes both the primary signal dimension and the at least one secondary signal dimension, is utilized to determine the second signal representation of the subject, which may improve computational efficiency and reduce processing time.

It should be noted that the above descriptions regarding the processes 1400A and 1400B are merely provided for the purposes of illustration, and not intended to limit the scope of the present disclosure. For persons having ordinary skills in the art, multiple variations or modifications may be made under the teachings of the present disclosure. However, those variations and modifications do not depart from the scope of the present disclosure.

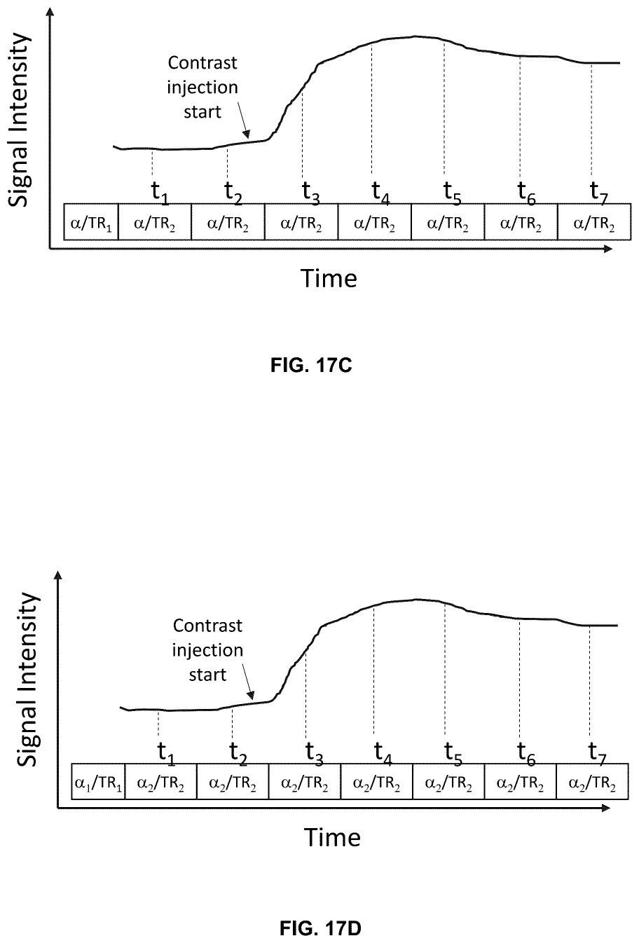

FIG. 15 is a flowchart illustrating an exemplary process for MRI according to some embodiments of the present disclosure. In some embodiments, the process 1500 may be implemented in the MRI system 100 illustrated in FIG. 1. For example, the process 1500 may be stored in the storage device 130 and/or the storage (e.g., the storage 320, the storage 490) as a form of instructions, and invoked and/or executed by the processing device 120 (e.g., the processor 310 of the computing device 300 as illustrated in FIG. 3, the CPU 440 of the mobile device 400 as illustrated in FIG. 4, or one or more modules illustrated in FIG. 5). The operations of the illustrated process presented below are intended to be illustrative. In some embodiments, the process 1500 may be accomplished with one or more additional operations not described, and/or without one or more of the operations discussed. Additionally, the order in which the operations of the process 1500 as illustrated in FIG. 15 and described below is not intended to be limiting.

In some embodiments, one or more operations of the process 1500 may be performed to achieve at least part of operation 1330 as described in connection with FIG. 13.

In 1510, the processing device 120 may determine a first value and a second value relating to the second signal representation of the subject based on the second imaging data corresponding to at least one pair of adjacent echoes.

The first value may represent a signal representation along a first direction of the primary signal dimension. The second value may represent a signal representation along a second direction of the primary signal dimension. The first direction may be opposite to the second direction. For example, the primary signal dimension is the echo time, the first direction may be a direction in which the echo time increases (i.e., a direction in which the time elapses), and the second direction may be a direction in which the echo time decreases (i.e., a direction in which the time retrogrades).

The determination of the first value of the second signal representation may be found elsewhere in the present disclosure (e.g., FIGS. 14A and 14B, and the descriptions thereof).

In some embodiments, the determination of the second value of the second signal representation may be performed in a similar manner as that of the first value of the second signal representation.

For example, for each of at least one value in the at least one secondary signal dimension, the processing device 120 may determine a third preliminary signal representation along the second direction of the primary signal dimension based on a portion of the second imaging data corresponding to the value of the at least one secondary signal dimension. Further, the processing device 120 may determine the second value of the second signal representation based on at least a portion of the at least one third preliminary signal representation.

Merely by way of example, for Coil₁, the processing device 120 may determine at least one third preliminary signal representation based on the signals of Pᵣ corresponding to Coil₁, that is,

$${S}_{{e}_{1}}^{1} ( r ) to {S}_{{e}_{n}}^{1} ( r ) .$$

The at least one third preliminary signal representation may include

$$Δ {S}_{1 - 2}^{1} ( r ) , Δ {S}_{2 - 3}^{1} ( r ) , … , and Δ {S}_{( n - 1 ) - n}^{1} ( r ) ,$$

wherein

$$Δ {S}_{( i - 1 ) - i}^{1} ( r )$$

refers to a change of signal intensity with respect to Coil₁ at Pᵣ as the echo time decreases (i.e., a direction in which the time retrogrades).

$$Δ {S}_{( i - 1 ) - i}^{1} ( r )$$

may be determined based on

$${S}_{{e}_{i}}^{1} ( r ) and {S}_{{e}_{i - 1}}^{1} ( r )$$

(the second imaging data corresponding to a pair of adjacent echoes). For example,

$$Δ {S}_{( i - 1 ) - i}^{1} ( r )$$

may be equal to

$${S}_{{e}_{i - 1}}^{1} ( r ) / {S}_{{e}_{i}}^{1} ( r ) .$$

Similarly, the processing device 120 may determine at least one third preliminary signal representation for each of the other coil units. In this way, m*(n−1) third preliminary signal representations of Pᵣ may be determined. In some embodiments, the processing device 120 may determine at least one third preliminary signal representation for a portion of the coil units. In this way, fewer than m*(n−1) third preliminary signal representations of Pᵣ may need to be determined. In some embodiments, the second value of the second signal representation may be a sum, an average value, or a median value of the at least a portion of the at least one third preliminary signal representation. In some embodiments, all of the at least one third preliminary signal representation may be used to determine the second value of the second signal representation of the subject. Alternatively, only a portion of the at least one third preliminary signal representation may be used to determine the second value of the second signal representation of the subject. Taking the example illustrated in FIG. 13 as an instance, the processing device 120 may determine the second value of the second signal representation based on the third preliminary signal representations corresponding to Coil₁ to Coilₘ₋₁, for example, if Coilₘ has some operation faults.

As another example, the processing device 120 may obtain a third optimization model of the second signal representation incorporating the primary signal dimension along the second direction. Further, the processing device 120 may determine the second value of the second signal representation of the subject by inputting the second imaging data into the third optimization model.

For illustration purposes, it is assumed that the subject is a physical point of an object, the second signal representation to be determined is ΔS1(r) (i.e., the change of signal intensity at the physical point with an echo time). As described above, the primary signal dimension associated with ΔS1(r) may be the echo time, and the at least one secondary signal dimension may include the coil unit. If the first direction is the direction in which the echo time increases, the second optimization model may be expressed as Equation (24) (similar to Equation (23)) as below:

$$arg {min}_{Δ S 1 {( r )}_{+}} {\sum }_{i = 1}^{{N}_{e} - 1} {\sum }_{j = 1}^{{N}_{c}} {‖ {S}_{i + 1 , j} ( r ) - {S}_{i , j} ( r ) Δ S 1 {( r )}_{+} ‖}_{2}^{2} , \qquad ( 24 )$$

where ΔS1(r)₊ denotes the first value of the second signal representation along the direction in which the echo time increases (i.e., the degree of attenuation of signal intensity at the physical point P, of the patient as the echo time increases ΔTE), i denotes a number of an echo, j denotes a number of a coil unit, Nₑ refers the count of values in the echo time dimension, N_{c} refers to the count of values in the coil unit, and S_{i+1,j}(r) and S_{i,j}(r) refer to the second imaging data corresponding to two successive (adjacent) echoes i and i+1 detected by one coil unit j.

If the second direction is the direction in which the echo time decreases, the third optimization model may be expressed as Equation (25) as below:

$$arg {min}_{Δ S 1 {( r )}_{-}} {\sum }_{i = 1}^{{N}_{e} - 1} {\sum }_{j = 1}^{{N}_{c}} {‖ {S}_{i + 1 , j} ( r ) Δ S 1 {( r )}_{-} - {S}_{i , j} ( r ) ‖}_{2}^{2} , \qquad ( 25 )$$

where ΔS1(r)₋ denotes the second value of the second signal representation along the direction in which the echo time decreases (i.e., the degree of enhancement of signal intensity at the physical point P, of the patient as the echo time decreases ΔTE).

It should be noted that the Equations (24) and (25) illustrated above are merely provided for the purposes of illustration, and not intended to limit the scope of the present disclosure. In some embodiments, the signals of the physical point may have one or more other secondary signal dimensions, and the other secondary signal dimension(s) may be incorporated in the Equations (24) and (25), for example, in a similar manner as the coil unit.

The processing device 120 may input the signals corresponding to the physical point into Equation (24) (or Equation (25)) and solve Equation (24) (or Equation (25)) to determine ΔS1(r). For example, the determination of a value of the ΔS1(r)₊ by solving the Equation (24) is described in Equation (26) as below:

$$Δ S 1 {( r )}_{+} = \frac{{\sum }_{i}^{{N}_{e} - 1} {\sum }_{j}^{{N}_{c}} {{S}_{i , j} ( r )}^{*} \cdot {S}_{i + 1 , j} ( r )}{{\sum }_{i}^{{N}_{e} - 1} {\sum }_{j}^{{N}_{c}} {\vert {S}_{i , j} ( r ) \vert}^{2}} , \qquad ( 26 )$$

The determination of a value of the ΔS1(r)₋ by solving the Equation (25) is described in Equation (27) as below:

$$Δ S 1 {( r )}_{-} = \frac{{\sum }_{i}^{{N}_{e} - 1} {\sum }_{j}^{{N}_{c}} {{S}_{i + 1 , j} ( r )}^{*} \cdot {S}_{i , j} ( r )}{{\sum }_{i}^{{N}_{e} - 1} {\sum }_{j}^{{N}_{c}} {\vert {S}_{i + 1 , j} ( r ) \vert}^{2}} , \qquad ( 27 )$$

In some embodiments, the processing device 120 may solve the second optimization model and the third optimization model using a least square method, a neural network model, a support vector machine (SVM), or the like, or any combination thereof.

In 1520, the processing device 120 (e.g., the determination module 304) may determine a value of a quantitative parameter of the subject based on the first value and the second value.

In some embodiments, the primary signal dimension may be an echo time, and the quantitative parameter may be the transverse relaxation time T2* and/or the transverse relaxation rate R2* (R2*=1/T2*), the field distribution, or the like, or any combination thereof.

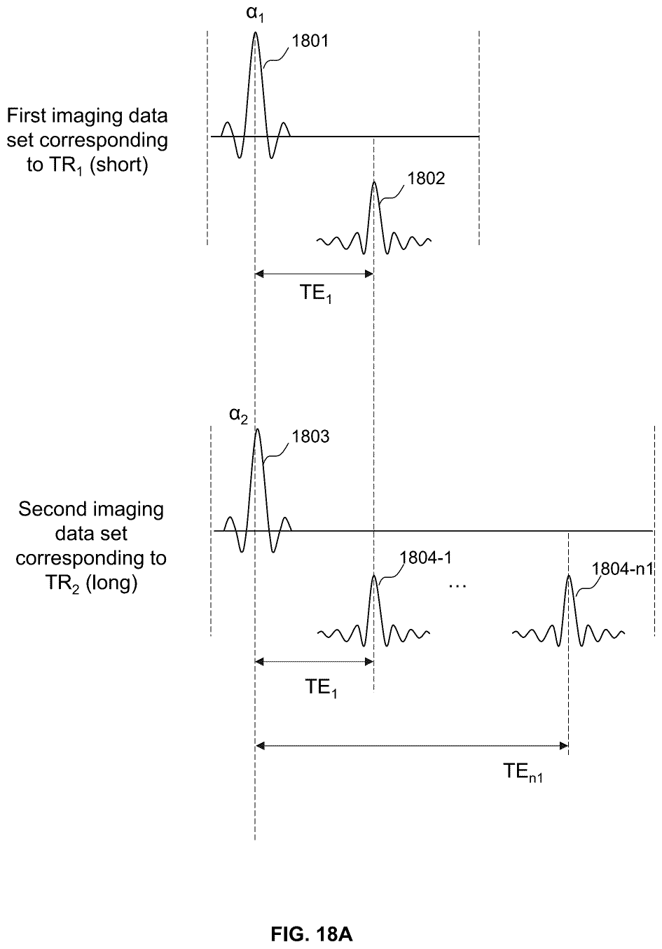

In some embodiments, the processing device 120 may determine a first preliminary value of the quantitative parameter of the subject based on the first value. The processing device 120 may also determine a second preliminary value of the quantitative parameter of the subject based on the second value. Further, the processing device 120 may determine the value of the quantitative parameter of the subject based on the first preliminary value and the second preliminary value of the quantitative parameter. More descriptions regarding the determination of the value of the quantitative parameter of the subject may be found elsewhere in the present disclosure (e.g., FIG. 16, and the descriptions thereof).

FIG. 16 is a flowchart illustrating an exemplary process for determining a value of a quantitative parameter according to some embodiments of the present disclosure. In some embodiments, the process 1600 may be implemented in the MRI system 100 illustrated in FIG. 1. For example, the process 1600 may be stored in the storage device 130 and/or the storage (e.g., the storage 320, the storage 490) as a form of instructions, and invoked and/or executed by the processing device 120 (e.g., the processor 310 of the computing device 300 as illustrated in FIG. 3, the CPU 440 of the mobile device 400 as illustrated in FIG. 4, or one or more modules illustrated in FIG. 5). The operations of the illustrated process presented below are intended to be illustrative. In some embodiments, the process 1600 may be accomplished with one or more additional operations not described, and/or without one or more of the operations discussed. Additionally, the order in which the operations of the process 1600 as illustrated in FIG. 16 and described below is not intended to be limiting.

In some embodiments, one or more operations of the process 1600 may be performed to achieve at least part of operation 1520 as described in connection with FIG. 15.

In 1610, the processing device 120 (e.g., the determination module 304) may determine, based on the first value, a first preliminary value of the quantitative parameter of the subject.

In some embodiments, the processing device 120 may obtain a first relationship relating to the second signal representation and the quantitative parameter along the first direction of the primary signal dimension. The processing device 120 may determine the first preliminary value of the quantitative parameter of the subject based on the first value of the second signal representation and the first relationship. For example, the first relationship may be described in the form of a correlation function, such as Equation (21). The processing device 120 may determine the first preliminary value of the quantitative parameter by solving the correlation function. As another example, the first relationship may be presented in the form of a table or curve recording different second signal representations and their corresponding first preliminary values of the quantitative parameter. The processing device 120 may determine the first preliminary value of the quantitative parameter by looking up the table or consulting the curve.

In some embodiments, the second signal representation of the subject may be represented by a complex number including a phase component and an amplitude component. The first preliminary value of the quantitative parameter may be determined based on at least one of the phase component or the amplitude component of the complex number. Alternatively, the second signal representation may be represented by a real number, and the first preliminary value of the quantitative parameter may be determined based on the real number. Taking the physical point Pᵣ as an example, if the first direction is the direction in which the echo time increases, and the first value of the second signal representation is ΔS1(r)₊ described above, a first preliminary value of

$${T}_{2}^{*} ( r )$$

at Pᵣ (denoted as

$${T}_{2 +}^{*} ( r ) )$$

and/or a first preliminary value of

$${R}_{2}^{*} ( r )$$

at Pᵣ (denoted as

$${R}_{2 +}^{*} ( r ) )$$

may be determined, wherein

$${R}_{2}^{*} ( r )$$

refers to a transverse relaxation rate of Pᵣ. Typically, it is considered that the values of

$${T}_{2}^{*} ( r ) and {R}_{2}^{*} ( r )$$

determined based on the value of the second signal representation of the subject along a same direction of the primary signal dimension are reciprocals of each other, that is,

$${R}_{2 +}^{*} ( r ) and {T}_{2 +}^{*} ( r )$$

are reciprocals of each other, and

$${R}_{2 -}^{*} ( r ) and {T}_{2 -}^{*} ( r )$$

described in operation 1620 are reciprocals of each other. If ΔS1(r)₊ is a real number,

$${T}_{2 +}^{*} ( r ) and {R}_{2 +}^{*} ( r )$$

may be determined based on ΔS1(r)₊. If ΔS1(r)₊ is a complex number,

$${T}_{2 +}^{*} ( r ) and {R}_{2 +}^{*} ( r )$$

may be determined based on the amplitude component of ΔS1(r)₊. For example, the determination of

$${T}_{2 +}^{*} ( r ) and {R}_{2 +}^{*} ( r )$$

based on ΔS1(r)₊ is described in Equations (28) and (29) as below:

$${T}_{2 +}^{*} ( r ) = - Δ TE / ln ( \vert Δ S 1 {( r )}_{+} \vert ) , \qquad ( 28 )$$

$$and$$

$${R}_{2 +}^{*} ( r ) = - ln ( \vert Δ S 1 {( r )}_{+} \vert ) / Δ TE , \qquad ( 29 )$$

In 1620, the processing device 120 may determine, based on the second value, a second preliminary value of the quantitative parameter.

In some embodiments, the processing device 120 may obtain a second relationship relating to the second signal representation and the quantitative parameter along the second direction of the primary signal dimension. Further, the processing device 120 may determine the second preliminary value of the quantitative parameter of the subject based on the second value of the second signal representation and the second relationship. In some embodiments, the determination of the second preliminary value of the quantitative parameter may be performed in a similar manner as that of the first preliminary value of the quantitative parameter. For example, taking the physical point Pᵣ as an example, if the second direction is the direction in which the echo time decreases, and the second value of the second signal representation is ΔS1(r)₋ described above, a second preliminary value of

$${T}_{2}^{*} ( r )$$

at Pᵣ (denoted as

$${T}_{2 -}^{*} ( r ) )$$

and/or a second preliminary value of

$${R}_{2}^{*} ( r )$$

at Pᵣ (denoted as

$${R}_{2 -}^{*} ( r ) )$$

may be determined. If ΔS1(r)₋ is a real number,

$${T}_{2 -}^{*} ( r ) and {R}_{2 -}^{*} ( r )$$

may be determined based on ΔS1(r)₋. If ΔS1(r)₋ is a complex number,

$${T}_{2 -}^{*} ( r ) and {R}_{2 -}^{*} ( r )$$

may be determined based on the amplitude component of ΔS1(r)₋. For example, the determination of

$${T}_{2 -}^{*} ( r ) and {R}_{2 -}^{*} ( r )$$

based on the ΔS1(r)₋ is described in Equation (30) and Equation (31) as below:

$${T}_{2 -}^{*} ( r ) = Δ TE / ln ( \vert Δ S 1 {( r )}_{-} \vert ) , \qquad ( 30 )$$

$$and$$

$${R}_{2 -}^{*} ( r ) = ln ( \vert Δ S 1 {( r )}_{-} \vert ) / Δ TE , \qquad ( 31 )$$

In 1630, the processing device 120 may determine, based on the first preliminary value and the second preliminary value, the value of the quantitative parameter of the subject.

Since one of the first preliminary value and the second preliminary value usually is smaller than the true value of the quantitative parameter, and the other of the first preliminary value and the second preliminary value usually is greater than the true value of the quantitative parameter, the defects of the first preliminary value and the second preliminary value may be made up for each other by combining the first preliminary value and the second preliminary value. Therefore, in some embodiments, the processing device 120 may determine the value of the quantitative parameter of the subject by combining the first preliminary value and the second preliminary value. In some embodiments, the quantitative parameter of the subject is the transverse relaxation rate

$${R}_{2}^{*} ( r ) ,$$

and the processing device 120 may designate an average of the first preliminary value

$${R}_{2 +}^{*} ( r )$$

and the second preliminary value

$${R}_{2 -}^{*} ( r )$$

as the value of the transverse relaxation rate

$${R}_{2}^{*} ( r ) .$$

Merely by way of example, the value of

$${R}_{2}^{*} ( r )$$

may be determined based on the

$${R}_{2 +}^{*} ( r ) and {R}_{2 -}^{*} ( r )$$

according to Equation (32) as below:

$${R}_{2}^{*} ( r ) = \frac{{R}_{2 +}^{*} ( r ) + {R}_{2 -}^{*} ( r )}{2} , \qquad ( 32 )$$

In some embodiments, the quantitative parameter of the subject is the transverse relaxation time

$${T}_{2}^{*} ( r ) ,$$

the processing device 120 may determine a first reciprocal of the first preliminary value

$${T}_{2 +}^{*} ( r )$$

and a second reciprocal of the second preliminary value

$${T}_{2 -}^{*} ( r ) ,$$

and determine the value of the transverse relaxation time

$${T}_{2}^{*} ( r )$$

based on the first reciprocal and the second reciprocal. Merely by way of example, the value of

$${T}_{2}^{*} ( r )$$

may be determined based on the

$${T}_{2 +}^{*} ( r ) and {T}_{2 -}^{*} ( r )$$

according to Equation (33) as below:

$${T}_{2}^{*} ( r ) = {( \frac{\vert \frac{1}{{T}_{2 +}^{*} ( r )} \vert + \vert \frac{1}{{T}_{2 -}^{*} ( r )} \vert}{2} )}^{- 1} . \qquad ( 33 )$$

Compared with the first preliminary value and the second preliminary value of the quantitative parameter, the value of the quantitative parameter determined by combining the first preliminary value and the second preliminary value may be closer to the actual value of the quantitative parameter and have a greater accuracy. In some embodiments, as the SNR decreases, the impact of noise on the first and second preliminary values become greater and greater, that is, a difference between the first preliminary value and the true value of the quantitative parameter and a difference between the second preliminary value and the true value of the quantitative parameter become larger and larger, the accuracy of the first and second preliminary values gradually decrease. According to some embodiments of the present disclosure, the value of the quantitative parameter determined by combining the first preliminary value and the second preliminary value may have a relatively high accuracy when the SNR is relatively low.

In the present disclosure, a plurality of imaging data sets are collected based on two or more different values of a scan parameter. In at least one of the plurality of imaging data sets, two or more echoes are generated in a TR. By introducing two or more echoes generated in a TR into the plurality of imaging data sets, T1 weighted imaging and T1 mapping can be achieved with the interference of non-T1 factors being eliminated or alleviated and the signal-to-noise ratio being improved, and T2* weighted imaging and T2* mapping can also be achieved using the plurality of imaging data sets.

Having thus described the basic concepts, it may be rather apparent to those skilled in the art after reading this detailed disclosure that the foregoing detailed disclosure is intended to be presented by way of example only and is not limiting. Various alterations, improvements, and modifications may occur and are intended to those skilled in the art, though not expressly stated herein. These alterations, improvements, and modifications are intended to be suggested by this disclosure, and are within the spirit and scope of the exemplary embodiments of this disclosure.

Moreover, certain terminology has been used to describe embodiments of the present disclosure. For example, the terms “one embodiment,” “an embodiment,” and “some embodiments” mean that a particular feature, structure or characteristic described in connection with the embodiment is included in at least one embodiment of the present disclosure. Therefore, it is emphasized and should be appreciated that two or more references to “an embodiment” or “one embodiment” or “an alternative embodiment” in various portions of this specification are not necessarily all referring to the same embodiment. Furthermore, the particular features, structures or characteristics may be combined as suitable in one or more embodiments of the present disclosure.

Further, it will be appreciated by one skilled in the art, aspects of the present disclosure may be illustrated and described herein in any of a number of patentable classes or context including any new and useful process, machine, manufacture, or composition of matter, or any new and useful improvement thereof. Accordingly, aspects of the present disclosure may be implemented entirely hardware, entirely software (including firmware, resident software, micro-code, etc.) or combining software and hardware implementation that may all generally be referred to herein as a “module,” “unit,” “component,” “device,” or “system.” Furthermore, aspects of the present disclosure may take the form of a computer program product embodied in one or more computer readable media having computer readable program code embodied thereon.

A computer readable signal medium may include a propagated data signal with computer readable program code embodied therein, for example, in baseband or as part of a carrier wave. Such a propagated signal may take any of a variety of forms, including electro-magnetic, optical, or the like, or any suitable combination thereof. A computer readable signal medium may be any computer readable medium that is not a computer readable storage medium and that may communicate, propagate, or transport a program for use by or in connection with an instruction execution system, apparatus, or device. Program code embodied on a computer readable signal medium may be transmitted using any appropriate medium, including wireless, wireline, optical fiber cable, RF, or the like, or any suitable combination of the foregoing.

Computer program code for carrying out operations for aspects of the present disclosure may be written in any combination of one or more programming languages, including an object oriented programming language such as Java, Scala, Smalltalk, Eiffel, JADE, Emerald, C++, C#, VB. NET, Python or the like, conventional procedural programming languages, such as the “C” programming language, Visual Basic, Fortran 2003, Perl, COBOL 2002, PHP, ABAP, dynamic programming languages such as Python, Ruby and Groovy, or other programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider) or in a cloud computing environment or offered as a service such as a Software as a Service (SaaS).

Furthermore, the recited order of processing elements or sequences, or the use of numbers, letters, or other designations therefore, is not intended to limit the claimed processes and methods to any order except as may be specified in the claims. Although the above disclosure discusses through various examples what is currently considered to be a variety of useful embodiments of the disclosure, it is to be understood that such detail is solely for that purpose, and that the appended claims are not limited to the disclosed embodiments, but, on the contrary, are intended to cover modifications and equivalent arrangements that are within the spirit and scope of the disclosed embodiments. For example, although the implementation of various components described above may be embodied in a hardware device, it may also be implemented as a software only solution, e.g., an installation on an existing server or mobile device.

Similarly, it should be appreciated that in the foregoing description of embodiments of the present disclosure, various features are sometimes grouped together in a single embodiment, figure, or description thereof for the purpose of streamlining the disclosure aiding in the understanding of one or more of the various embodiments. This method of disclosure, however, is not to be interpreted as reflecting an intention that the claimed subject matter requires more features than are expressly recited in each claim. Rather, claim subject matter lie in less than all features of a single foregoing disclosed embodiment.

What is claimed is:

1. A method for magnetic resonance imaging (MRI) implemented on a computing device having at least one processing device and at least one storage device, the method comprising:
obtaining a plurality of imaging data sets that are related to a region of interest (ROI) of a subject and generated using a magnetic resonance imaging (MRI) device, the plurality of imaging data sets being collected based on two or more different values of a scan parameter;
determining at least one group of imaging data based on the plurality of imaging data sets, wherein each of the at least one group of imaging data includes a first imaging data set and a second imaging data set corresponding to two of the two or more different values of the scan parameter, and for at least one of the first imaging data set or the second imaging data set, two or more echoes are generated in a repetition time (TR); and
for each of the at least one group of imaging data, generating a T1 weighted image and/or a quantitative T1 map of the ROI based on first imaging data corresponding to at least one pair of echoes each of which is with the same echo time (TE) in the first imaging data set and the second imaging data set.

2. The method of claim 1, wherein
any two adjacent imaging data sets of the plurality of imaging data sets correspond to two of the two or more different values of the scan parameter; and
the first imaging data set and the second imaging data set are two adjacent imaging data sets of the plurality of imaging data sets.

3. The method of claim 1, wherein
at least one of the plurality of imaging data sets corresponding to a first value of the two or more different values of the scan parameter is collected before the rest of the plurality of imaging data sets corresponding to the rest of the two or more different values of the scan parameter;
the first imaging data set is obtained by determining an average of the at least one imaging data sets corresponding to the first value of the scan parameter; and
the second imaging data set is one of the rest of the plurality of imaging data sets corresponding to the rest of the two or more different values of the scan parameter.

4. The method of claim 1, wherein the scan parameter includes at least one of a flip angle or a repetition time (TR).

5. The method of claim 4, wherein
the first imaging data set and the second imaging data set corresponding to different values of the flip angle and a fixed value of the TR; or
the first imaging data set and the second imaging data set correspond to different values of the TR and a fixed value of the flip angle; or
the first imaging data set and the second imaging data set correspond to different values of the flip angle and different values of the TR.

6. The method of claim 1, wherein the generating a T1 weighted image of the ROI based on first imaging data corresponding to at least one pair of echoes includes:
determining a first signal representation of the ROI based on the first imaging data, the first signal representation indicating a signal change of two echoes with the same TE in the first imaging data set and the second imaging data set; and
generating, based on the first signal representation, the T1 weighted image of the ROI.

7. The method of claim 6, wherein the first signal representation is defined as a ratio between imaging data related to two echoes with the same TE in the first imaging data set and the second imaging data set.

8. The method of claim 6, wherein the determining a first signal representation of the ROI based on the first imaging data corresponding to the at least one pair of echoes includes:
establishing a first optimization model based on the first imaging data and the first signal representation; and
determining the first signal representation by minimizing a value of the first optimization model.

9. The method of claim 6, wherein the determining a first signal representation of the ROI based on the first imaging data corresponding to the at least one pair of echoes includes:
for each of the at least one pair of echoes, determining a first preliminary signal representation of the ROI based on the first imaging data corresponding to the pair of echoes; and
determining the first signal representation based on the first preliminary signal representation corresponding to the at least one pair of echoes.

10. The method of claim 1, further comprising:
determining, as a target imaging data set, one of the plurality of imaging data set in which two or more echoes are generated in a TR; and
determining a second signal representation of the ROI based on second imaging data corresponding to at least one pair of adjacent echoes of the two or more echoes in the target imaging data set, the second signal representation indicating a signal change of two adjacent echoes in the TR.

11. The method of claim 10, wherein the determining a second signal representation includes:
determining the second signal representation of the ROI based on the second imaging data corresponding to the at least one pair of adjacent echoes of the two or more echoes in the target imaging data set, a primary signal dimension, and at least one secondary signal dimension, the primary signal dimension being the TE, the at least one secondary signal dimension being not associated with the second signal representation.

12. The method of claim 10, wherein the determining a second signal representation includes:
for each pair of adjacent echoes in the target imaging data set, determining at least one second preliminary signal representation based on the second imaging data related to the pair of adjacent echoes; and
determining, based on the at least one second preliminary signal representation of the subject, the second signal representation of the subject.

13. The method of claim 10, wherein the determining a second signal representation includes:
establishing a second optimization model based on the second signal representation and the second imaging data; and
determining the second signal representation by minimizing a value of the second optimization model.

14. The method of claim 10, further comprising:
generating a T2* weighted image based on the second signal representation; and/or
determining, based on the second signal representation of the subject, a value of a quantitative parameter of the subject, the quantitative parameter including a transverse relaxation time T2* and/or a transverse relaxation rate R2*.

15. The method of claim 14, wherein the determining a value of a quantitative parameter of the subject includes:
determining a first value and a second value relating to the second signal representation of the subject based on the second imaging data, wherein the first value represents a signal representation along a first direction in which the time elapses, the second value represents a signal representation along a second direction in which the time retrogrades; and
determining the value of the quantitative parameter of the subject based on the first value and the second value.

16. The method of claim 15, wherein the determining the value of the quantitative parameter of the subject based on the first value and the second value includes:
determining, based on the first value, a first preliminary value of the quantitative parameter of the subject;
determining, based on the second value, a second preliminary value of the quantitative parameter of the subject; and
determining, based on the first preliminary value and the second preliminary value, the value of the quantitative parameter of the subject.

17. The method of claim 16, wherein the quantitative parameter of the subject is T2*, and the determining, based on the first preliminary value and the second preliminary value, the value of the quantitative parameter of the subject includes:
determining, a first reciprocal of the first preliminary value and a second reciprocal of the second preliminary value; and
determining, based on the first reciprocal and the second reciprocal, the value of T2*; or
wherein the quantitative parameter of the subject is R2*, and the determining, based on the first preliminary value and the second preliminary value, the value of the quantitative parameter of the subject includes:
designating an average of the first preliminary value and the second preliminary value as the value of the transverse relaxation rate.

18. The method of claim 14, wherein:
the second signal representation is represented by a complex number including a phase component and an amplitude component, and the value of the quantitative parameter is determined based on at least one of the phase component or the amplitude component of the complex number, or
the second signal representation is represented by a real number, and the value of the quantitative parameter of interest is determined based on the real number.

19. A magnetic resonance imaging (MRI) system, comprising:
at least one storage device including a set of instructions; and
at least one processor in communication with the at least one storage device, wherein when executing the set of instructions, the at least one processor is configured to direct the system to perform operations including:
obtaining a plurality of imaging data sets that are related to a region of interest (ROI) of a subject and generated using a magnetic resonance imaging (MRI) device, the plurality of imaging data sets being collected based on two or more different values of a scan parameter;
determining at least one group of imaging data based on the plurality of imaging data sets, wherein each of the at least one group of imaging data includes a first imaging data set and a second imaging data set corresponding to two of the two or more different values of the scan parameter, and for at least one of the first imaging data set or the second imaging data set, two or more echoes are generated in a repetition time (TR); and
for each of the at least one group of imaging data, generating a T1 weighted image and/or a quantitative T1 map of the ROI based on first imaging data corresponding to at least one pair of echoes each of which is with the same echo time (TE) in the first imaging data set and the second imaging data set.

20. A non-transitory computer readable medium, comprising at least one set of instructions for magnetic resonance imaging (MRI), wherein when executed by one or more processors of a computing device, the at least one set of instructions causes the computing device to perform a method, the method comprising:
obtaining a plurality of imaging data sets that are related to a region of interest (ROI) of a subject and generated using a magnetic resonance imaging (MRI) device, the plurality of imaging data sets being collected based on two or more different values of a scan parameter;
determining at least one group of imaging data based on the plurality of imaging data sets, wherein each of the at least one group of imaging data includes a first imaging data set and a second imaging data set corresponding to two of the two or more different values of the scan parameter, and for at least one of the first imaging data set or the second imaging data set, two or more echoes are generated in a repetition time (TR); and
for each of the at least one group of imaging data, generating a T1 weighted image and/or a quantitative T1 map of the ROI based on first imaging data corresponding to at least one pair of echoes each of which is with the same echo time (TE) in the first imaging data set and the second imaging data set.
